(19) United States
(12) Patent Application Publication
(10) Pub. No.: US 2012/0144275 A1
(43) Pub. Date: Jun. 7, 2012

(54) CODE GENERATING DEVICE AND CODE GENERATING METHOD, CODE CHECKING DEVICE AND CODE CHECKING METHOD, COMPUTER PROGRAM, AND COMMUNICATION DEVICE

(75) Inventors: Kentaro Odaka, Tokyo (JP); Fumihiro Nishiyama, Saitama (JP); Katsumi Watanabe, Tokyo (JP)

(73) Assignee: Sony Corporation, Tokyo (JP)

(21) Appl. No.: 13/304,923

(22) Filed: Nov. 28, 2011

(30) Foreign Application Priority Data
Dec. 6, 2010 (JP) P2010-272028

(51) Int. Cl. H03M 13/09; G06F 11/10

(52) U.S. Cl. 714/800; 714/799; 714/E11.032

(57) ABSTRACT

A code generating device includes a code word generating section which generates a code word with a predetermined code word length by applying a second matrix Gq of a second error detection method with regard to an information word A′ which has been input, and a code word conversion section which converts the code word generated by the code word generating section based on an added fixed value (Qa+Pa) which is formed from respective code words Qa and Pa which are obtained by the second matrix Gq and a first matrix Gp of a first error detection method being respectively applied to an information word A which is formed from a specific data string.

### CROSS-REFERENCE TO RELATED APPLICATION

The present application claims priority from Japanese Patent Application No. JP 2010-272028 filed in the Japanese Patent Office on Dec. 6, 2010, the entire content of which is incorporated herein by reference.

### BACKGROUND

The present disclosure relates to a code generating device and a code generating method, a code checking device and a code checking method, a computer program, and a communication device which are applied for error detection or error detection correction of transmission data in a communication system, an information recording system, or the like.

In more detail, the present disclosure relates to a code generating device and a code generating method which generate error detection code which is compatible with another error detection method with the same code word length, to a code checking device and a code checking method which perform error detection from error detection code where the compatibility with another error detection method is ensured, and to a communication device, a communication method, and a computer program which adopt an error detection method where the compatibility with another error detection method is ensured.

In a communication system, an information recording system, or the like, errors occur in data when data is transmitted via a transmission path. As a result, in many communication systems and information recording systems, a technique of error detection and error detection correction is being introduced.

As an error checking method, CRC (Cyclic Redundancy Check) is widely known. In CRC, a generator polynomial is applied with regard to an information word which is a detection target such as transmission data and CRC code (parity) is generated. The CRC code has characteristics where the same code is necessarily generated from the same information word and a completely different code is generated when the data is different by even one byte. At the data transmission origin, when the CRC code is generated from a string of transmission data, the CRC code is attached to the transmission data as redundant data and transmitted. Then, at a data reception side, when the CRC code is generated form the received transmission data, the CRC code is compared with the redundant code attached to the transmission data and it is possible to check whether an error has occurred.

For example, there is a proposal with regard to a CRC coding circuit which selects a generator polynomial which is able to be used in a code length range which is as large as possible where the probability of undetected errors in the code is as low as possible and the smallest Hamming distance of the code is as large as possible in a given code length and parity length (for example, refer to Japanese Unexamined Patent Application Publication No. 2006-180172).

Currently, the application of error detection or error detection correction (referred to below as simply “error detection method”) is regulated in various standards in relation to communication systems and recording systems.

On the other hand, in accordance with the development of the techniques, updating of the content of the standards is also typical. Here, in accordance with the revision of the standards, there is assumed to be situations where the adopted error detection method is changed due to improvements in the error detection method and other aims. In a case such as this, if there is no compatibility with the standards before and after the revision, the users of existing devices which conformed with the standards before the revision incur a large loss. This is because if it is not possible to communicate between an existing device and a new device, the existing device is not able to be used when the new device becomes mainstream.

As a result, in a communication system, a recording system or the like, there is a strong demand for ensuring upward compatibility when changing the error detection method. That is, it is not only simply necessary for it to be possible to mutually understand error detection or error detection correction (referred to below as simply “error detection method”) with the new device, but it is necessary that the existing device is able to understand the error detection code received from the new device, and in addition, the new device is also able to understand the error detection code generated by the existing device.

### SUMMARY

It is desirable that a code generating device and a code generating method, a code checking device and a code checking method, a computer program, and a communication device are provided which are superior and are applied for error detection or error detection correction in a communication system, an information recording system, or the like.

It is also desirable that a code generating device and a code generating method, which generate error detection code which is compatible with another error detection method with the same code word length, a code checking device and a code checking method, which perform error detection from error detection code where the compatibility with another error detection method is ensured, and a communication device, a communication method, and a computer program, which adopt an error detection method where the compatibility with another error detection method is ensured, are provided.

A code generating device according to an embodiment of the disclosure is provided with a code word generating section which generates a code word with a predetermined code word length by applying a second matrix Gq of a second error detection method with regard to an information word A′ which has been input, and a code word conversion section which converts the code word generated by the code word generating section based on an added fixed value (Qa+Pa) which is formed from respective code words Qa and Pa which are obtained by the second matrix Gq and a first matrix Gp of a first error detection method being respectively applied to an information word A which is formed from a specific data string.

In the code generating device according to the embodiment of the disclosure, the code word conversion section of the code generating device may be configured so that the code word, which is generated by the code word generating section from the information word A′ which has been input, is convert based on the added fixed value (Qa+Pa) in accordance with a conversion method which converts the code word Qa, which is obtained by applying the second matrix Gq to the information word A which is formed from the specific data string, to the code word Pa, which is obtained by applying the first matrix Gp to the information word A.

In the code generating device according to the embodiment of the disclosure, the code word conversion section of the code generating device may be configured so as to convert by the added fixed value (Qa+Pa) being attached to the code word which is generated by the code word generating section from the information word A′ which has been input.

A code generating device according to another embodiment of the disclosure is provided with a fixed value holding section which holds a fixed value K from which an added fixed value (Qa+Pa), which is formed from respective code words Qa and Pa which are obtained by a second matrix Gq and a first matrix Gp of a first error detection method being respectively applied to an information word A which is formed from a specific data string, is able to be obtained when the second matrix Gq is applied after a bit position is shifted from a least significant bit to a higher order by n bits, a fixed value adding section which adds the fixed value K to an input information word A′ at a position which is shifted from a least significant bit to a higher order by n bits, and a code word generating section which generates a code word with a predetermined code word length by applying the second matrix Gq with regard to the information word A′ after the fixed value K is added.

A code generating method according to still another embodiment of the disclosure includes generating a code word with a predetermined code word length by applying a second matrix Gq of a second error detection method with regard to an information word A′ which has been input, and converting the generated code word based on an added fixed value (Qa+Pa) which is formed from respective code words Qa and Pa which are obtained by the second matrix Gq and a first matrix Gp of a first error detection method being respectively applied to an information word A which is formed from a specific data string.

A code checking device according to still another embodiment of the disclosure is provided with a code word generating section which inputs a code word generated using the code generating device with an original information word A′ and generates a code word with a predetermined code word length by applying a second matrix Gq of a second error detection method with regard to the original information word A′, a code word inverse conversion section which inversely converts the code word input with the original information word A′ based on an added fixed value (Qa+Pa) which is formed from respective code words Qa and Pa which are obtained by the second matrix Gq and a first matrix Gp of a first error detection method being respectively applied to an information word A which is formed from a specific data string, and a checking section which checks by comparing the code word generated by the code word generating section from the original information word A′ and the code word after inverse conversion by the code word inverse conversion section.

In the code checking device according to the still another embodiment of the disclosure, the code word inverse conversion section of the code checking device may be configured so that the code word which is input with the original information word A′ is inversely convert based on the added fixed value (Qa+Pa) in accordance with a conversion method which converts the code word Qa, which is obtained by applying the second matrix Gq to the information word A which is formed from the specific data string, to the code word Pa, which is obtained by applying the first matrix Gp to the information word A.

In the code checking device according to the still another embodiment of the disclosure, the code word inverse conversion section of the code checking device may be configured so as to inversely convert by the added fixed value (Qa+Pa) being attached to the code word which is input with the original information word A′.

A code checking device according to still another embodiment of the disclosure is provided with a fixed value holding section which inputs a code word generated using the code generating device with an original information word A′ and which holds a fixed value K from which an added fixed value (Qa+Pa), which is formed from respective code words Qa and Pa which are obtained by a second matrix Gq and a first matrix Gp of a first error detection method being respectively applied to an information word A which is formed from a specific data string, is able to be obtained when the second matrix Gq is applied after a bit position is shifted from a least significant bit to a higher order by n bits, a fixed value adding section which adds the fixed value K to the original information word A′ at a position which is shifted from a least significant bit to a higher order by n bits, a code word generating section which generates a code word with a predetermined code word length by applying the second matrix Gq to the information word A′ after the fixed value K is added, and a checking section which checks by comparing the code word generated by the code word generating section with the code word which was input with the original information word A′.

A code checking method according to still another embodiment of the disclosure includes inputting a code word generated using the code generating method with an original information word A′, generating a code word with a predetermined code word length by applying a second matrix Gq of a second error detection method with regard to the original information word A′, inversely converting the code word input with the original information word A′ based on an added fixed value (Qa+Pa) which is formed from respective code words Qa and Pa which are obtained by the second matrix Gq and a first matrix Gp of a first error detection method being respectively applied to an information word A which is formed from a specific data string, and checking by comparing the code word generated from the original information word A′ with the code word generating section and the code word after the inverse converting.

A computer program according to still another embodiment of the disclosure is written in a computer readable format so as to cause a computer to function as a code word generating section which generates a code word with a predetermined code word length by applying a second matrix Gq of a second error detection method with regard to an information word A′ which has been input, and a code word conversion section which converts the code word generated by the code word generating section based on an added fixed value (Qa+Pa) which is formed from respective code words Qa and Pa which are obtained by the second matrix Gq and a first matrix Gp of a first error detection method being respectively applied to an information word A which is formed from a specific data string.

The computer program according to the still another embodiment of the disclosure is defined as a computer program which is written in a computer readable format so as to realize a predetermined process on a computer. In other words, by installing the computer program according to still another embodiment of the disclosure in a computer, collaborative operations are exhibited in the computer and it is possible to obtain the same operational effects as the code generating device according to the embodiment of the disclosure.

In addition, a computer program according to still another embodiment of the disclosure is written in a computer readable format so as to cause a computer to function as a code word generating section which inputs a code word generated using the code generating device with an original information word A′ and generates a code word with a predetermined code word length by applying a second matrix Gq of a second error detection method with regard to the original information word A′, a code word inverse conversion section which inversely converts the code word input with the original information word A′ based on an added fixed value (Qa+Pa) which is formed from respective code words Qa and Pa which are obtained by the second matrix Gq and a first matrix Gp of a first error detection method being respectively applied to an information word A which is formed from a specific data string, and a checking section which checks by comparing the code word generated by the code word generating section from the original information word A′ and the code word after inverse conversion by the code word inverse conversion section.

The computer program according to the still another embodiment of the disclosure is defined as a computer program which is written in a computer readable format so as to realize a predetermined process on a computer. In other words, by installing the computer program according to still another embodiment of the disclosure in a computer, collaborative operations are exhibited in the computer and it is possible to obtain the same operational effects as the code checking device according to the still another embodiment of the disclosure.

In addition, a communication device according to still another embodiment of the disclosure is provided with a first transmission and reception processing section which generates a parity from transmission data and performs checking of a parity in accordance with a first error detection method, a second transmission and reception processing section which generates a parity from transmission data and performs checking of a parity in accordance with a second error detection method where the same parity as the first error detection method is generated only in regard to specific transmission data, and a communication control section which controls the first and second transmission and reception processing sections in accordance with a communication sequence.

In the communication device according to the still another embodiment of the disclosure, the first transmission and reception processing section of the communication device may be provided with a first parity generation section which generates a parity with a predetermined code word length by applying a first matrix Gp with regard to transmission data, and a first parity checking section which generates a parity by applying a first matrix Gp with regard to received data and performs error detection by comparing the generated parity with the parity which is connected to the received data. In addition, the second transmission and reception processing section may be provided with a second parity generating section which, after generating a parity with a predetermined code word length by applying a second matrix Gq with regard to transmission data, converts the generated parity using an added fixed value (Qa+Pa) which is formed from respective code words Qa and Pa which are obtained by the second matrix Gq and the first matrix Gp being respectively applied to specific transmission data, and a second parity checking section which generates a parity by applying the second matrix Gq with regard to received data, inversely converts the parity which is connected to the received data using the added fixed value (Qa+Pa), and performs error detection by comparing the generated parity with the inversely converted parity.

In the communication device according to the still another embodiment of the disclosure, the second parity generating section of the communication device may be configured so as to convert by the added fixed value (Qa+Pa) being attached to the parity which is generated by applying the second matrix Gq with regard to transmission data and the second parity checking section may be configured so as to inversely convert by the added fixed value (Qa+Pa) being attached to the parity which is connected to received data.

In the communication device according to the still another embodiment of the disclosure, the specific transmission data may include method information which shows which out of the first error detection method and the second error detection method is used in the following communication process, and the communication control section of the communication device may be configured so as to control a communication operation of the first transmission and reception processing section and the second transmission and reception processing section based on the method information which is included in the specific transmission data which is received by the second transmission and reception processing section.

In the communication device according to the still another embodiment of the disclosure, the communication device may apply a communication sequence where a connection is established via a connection request origin transmitting a connection request frame, a connection request destination replying with a connection request acceptance frame, and the connection request origin transmitting a confirmation response frame. Then, the specific transmission data is equivalent to a physical layer header of the connection request frame and may include method information which shows in the physical layer header which out of the first error detection method and the second error detection method is used in the following communication process.

In the communication device according to the still another embodiment of the disclosure, the communication control section of the communication device may be configured so as to make both the first and the second transmission and reception processing sections wait for reception of the connection request acceptance frame after transmitting the connection request frame, which includes the methods information showing the use of the second error detection method in the physical layer header, from the second transmission and reception processing section, establish a connection using the first error detection method, when the connection request acceptance frame is able to be received by the first transmission and reception processing section, by confirming that the method information which shows the use of the first error detection method is included in the physical layer header of the frame and transmitting the confirmation response frame from the first transmission and reception processing section, and establish a connection using the second error detection method, when the connection request acceptance frame is able to be received by the second transmission and reception processing section, by confirming that the method information which shows the use of the second error detection method is included in the physical layer header of the frame and transmitting the confirmation response frame from the second transmission and reception processing section.

In the communication device according to the still another embodiment of the disclosure, the communication control section of the communication device may be configured so as to make both the first and the second transmission and reception processing section wait for reception of the connection request frame, establish a connection using the first error detection method, when the connection request frame is able to be received by the second transmission and reception processing section, by confirming that the method information which shows the use of the second error detection method is included in the physical layer header of the frame, transmitting the connection request acceptance frame from the first transmission and reception processing section, and performing a confirmation response using the first transmission and reception processing section, and establish a connection using the first error detection method, when the connection request frame is able to be received by the first transmission and reception processing section, by confirming that the method information which shows the use of the first error detection method is included in the physical layer header of the frame, transmitting the connection request acceptance frame from the first transmission and reception processing section, and performing a confirmation response using the first transmission and reception processing section.

According to the embodiments of the disclosure, it is possible to provide a code generating device and a code generating method which generate error detection code which is compatible with another error detection method with the same code word length, a code checking device and a code checking method which perform error detection from error detection code where the compatibility with another error detection method is ensured, and a communication device, a communication method, and a computer program which adopt an error detection method where the compatibility with another error detection method is ensured.

According to the embodiments of the disclosure, it is possible to generate a code word where error detection is possible using either a first error detection method which uses a first matrix Gp or a second error detection method which uses a second matrix Gq from an information word A formed from a specific data string.

In a case where the code generating method according to the embodiments of the disclosure is used in a communication system, it is possible to perform decryption of transmission data, that is, error detection, using either a first error detection method or a second error detection method when transmitting specific data. Accordingly, when transmitting specific data (for example, a physical layer header of a connection request frame: to be described later) in order to start a sequence for establishing a connection between communication devices, by next determining to proceed with a process based on which of the error detection methods, it is possible to ensure compatibility between communication system standards which apply different error detection methods.

Other aims, characteristics, and advantages of the disclosure will be made clear due to a more detailed description based on the embodiments of the disclosure described below and the attached diagrams.

### BRIEF DESCRIPTION OF THE DRAWINGS

FIG. 1A is a diagram for describing a method where a code word which is generated using a second error detection method is converted to error detection code which ensures upward compatibility with a first error detection method;

FIG. 1B is a diagram for describing a method where a code word which is generated using a second error detection method is converted to error detection code which ensures upward compatibility with a first error detection method;

FIG. 2 is a diagram for describing another method where a code word which is generated using a second error detection method is converted to error detection code which ensures upward compatibility with a first error detection method;

FIG. 3 is a diagram illustrating one example of a frame format which is used in a communication system;

FIG. 4 is a diagram schematically illustrating a configuration example of a communication device which adopts a second error detection method and ensures upward compatibility with a first error detection method;

FIG. 5 is a diagram schematically illustrating a functional configuration of a code generating device for generating error detection code in a first transmission and reception processing section;

FIG. 6 is a diagram schematically illustrating a functional configuration of a code generating device for checking error detection code in a first transmission and reception processing section;

FIG. 7 is a diagram schematically illustrating a functional configuration of a code generating device for generating error detection code which is compatible with a first error detection method in a second transmission and reception processing section;

FIG. 8 is a diagram schematically illustrating a functional configuration of a code generating device for checking error detection code in a second transmission and reception processing section;

FIG. 9 is a diagram schematically illustrating a configuration example of a communication device which adopts a first error detection method (equivalent to an existing model);

FIG. 10 is a flowchart illustrating a process sequence executed when a communication device which adopts a second error detection method (refer to FIG. 4) requests connection with regard to a periphery communication device;

FIG. 11 is a flowchart illustrating a process sequence executed when a communication device which adopts a second error detection method (refer to FIG. 4) receives a connection request frame from a periphery communication device;

FIG. 12 is a diagram illustrating a communication sequence example where a connection is established by setting a header check sequence which has compatibility with a first error detection method using each management frame used in establishing the connection;

FIG. 13 is a diagram illustrating a communication sequence example where a connection is established by setting a header check sequence which has compatibility with a first error detection method using each management frame used in establishing the connection;

FIG. 14 is a diagram illustrating a communication sequence example where a connection is established by setting a header check sequence which has compatibility with a first error detection method using each management frame used in establishing the connection;

FIG. 15 is a diagram illustrating a communication sequence example where only a first error detection method is used in the performing of a sequence for establishing a connection and a probe is requested from a connection request origin after connection;

FIG. 16 is a diagram illustrating a communication sequence example where an error detection method is switched when frame resending has reached a time limit;

FIG. 17 is a diagram illustrating a communication sequence example where an error detection method is switched when frame resending has reached a time limit;

FIG. 18 is a diagram illustrating a communication sequence example where an error detection method is switched when frame resending has reached a time limit; and

FIG. 19 is a diagram illustrating an appearance where a C-Req frame is transmitted by a communication device which is a connection request origin alternately switching between CRC and ECS of a transmitter at a predetermined frequency and a communication device which is a connection request origin intermittently operates a receiver.

### DETAILED DESCRIPTION OF EMBODIMENTS

Below, embodiments of the disclosure will be described in detail while referencing the diagrams.

Below, in a communication system, a recording system, or the like which is standardized using a predetermined standard, a communication environment is assumed where two different types of methods coexist such as a first error detection method and a second error detection method as error detection methods. The coexisting of different methods in this manner depends on, for example, revisions in the standard and it is necessary that upward compatibility of the first error correction method which follows an existing standard with the second error detection method which follows a new standard is ensured. Below, the first error detection method is referred to as “ECS (Error Check Sequence)” (provisional name). In additional, it is possible to adopt CRC-16 as the second error detection method, and below, is simply referred to as “CRC”. Here, all of the calculations below are Mod2.

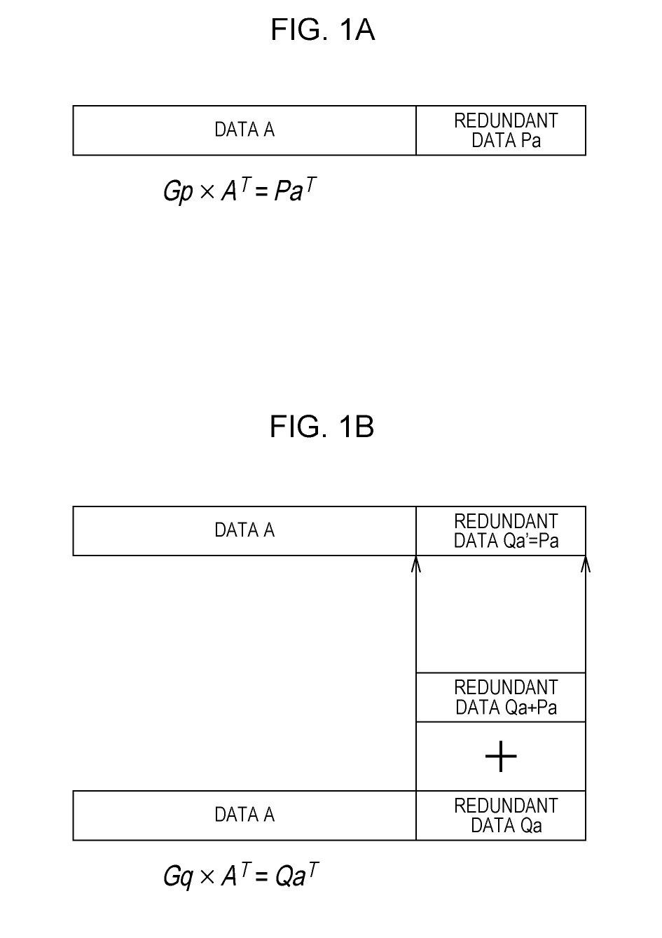

First, a method which generates error detection code, where upward compatibility of the first error detection method is ensured, using the second error method will be described while referencing FIGS. 1A and 1B.

A string of transmission data is set as A. In the first error detection method, transmission data is set (refer to FIG. 1A) by generating a code word (parity) Pa as shown in equation (1) from the data A using a parity generating matrix Gp which is formed from a predetermined generator polynomial and connecting the parity Pa to the rear of the data A as redundant code for error detection.

Gp×A^{T}=Pa^{T} (1)

On the other hand, in the second error detection method, a code word is generated using a parity generating matrix Gq which is formed from a generator polynomial different to that of the first error detection method. When the parity generating matrix Gq is applied to the data A, a parity Qa which is different to the parity Pa is generated as shown in equation (2). However, in addition, both of the parity generating matrices Gp and Gq necessarily generate the same code word from the same information word. In addition, code words with the same code word length are generated using either of the parity generating matrices Gp and Gq.

Gq×A^{T}=Qa^{T} (2)

In the second error detection method, when the parity Qa is used as is as the redundant code, it is different to Pa even if the code word length is the same as Pa. As a result, a communication device which conforms to the first error detection method is not able to generate the parity Qa from the data A when the transmission data where the parity Qa is connected to the data A is received and it is not possible to perform error detection processing. That is, there is no upward compatibility.

On the other hand, a value (Qa+Pa) where the parity Qa is added to the parity Pa which is generated using the parity generating matrix Gp from the same data A is added to the original parity Qa (that is, an exclusive OR is taken), conversion to the same redundant data Qa′ (=Pa) as the first error detection method is possible (refer to FIG. 1B).

Accordingly, when a communication device which conforms to the second error detection method transmits the data A, the parity Qa is generated from the data A using the parity generating matrix Gp and is converted to the redundant data Qa′ (=Pa) using a process as described in FIGS. 1A and 1B in the same manner described above, and if the redundant data Qa′ is connected to the transmission data A as a parity and transmitted, error detection or error detection correction is possible with the redundant data Qa′ as is even at the side of the communication device which conforms to the first error detection method. In addition, when the communication device which conforms to the second error detection method receives transmission data where the redundant code Pa is connected to the data A from the communication device which conforms to the first error detection method, since it is possible to inversely covert to the original redundant code Qa by adding Qa+Pa to the attached redundant code Pa (taking an exclusive OR), it is possible to perform error detection by applying the parity generating matrix Gq to the received data A.

Here, if the communication device which conforms to the second error detection method performs multiplication of the parity generating matrices Gp and Gq with regard to arbitrary transmission data A, it is possible for the redundant code Pa where error detection is possible to be generated even by the communication device which conforms to the first error detection method and it is possible to normally ensure upward compatibility. However, performing of the multiplication of the parity generating matrices twice each time a frame is transmitted makes calculation lengthy, and in addition, unnecessarily increases the burden of calculation processing.

The inventors consider the necessary use of redundant data which ensures the upward compatibility by the communication device which conforms to the second error detection method to be limited to a portion of management frames when transmitting. One example is when the communication device which conforms to the second error detection method is a connection request origin and there are management frames which request establishing of a connection for communication. In a sequence for establishing a connection, after a communication counterpart is determined to be the communication device which conforms to the first error detection method, since it is sufficient that the parity Pa in accordance with the first error detection method is directly determined by simply multiplying the parity generating matrix Gp to the transmission data A, it is not necessary that a complex calculation is performed where the parity Qa without compatibility is determined by multiplying the parity generating matrix Gq with the transmission data A, and is further converted to Pa with compatibility by adding Qa+Pa.

In addition, if the frame format is standardized so that the types of management frames in the sequence for establishing a connection are able to be written in a physical layer header of a frame, the communication device which conforms to the first error detection method is able to reply to a connection request acceptance frame with regard to a connection request if error detection or error detection correction only with regard to the physical layer header of the management frame is possible and it is possible to establish a connection.

In other words, it is sufficient if upward compatibility of the error detection method is ensured in the communication device which conforms to the second error detection method in regard to only the physical layer header of the management frame when requesting a connection. Referencing FIG. 1B, the data A, that is, the information word which is the target of the code, is equivalent to the physical layer header. Here, if limited to the connection request frame, since the descriptive content of the physical layer header, that is, the bit string of the data A, is fixed, the parities Pa and Qa which are respectively generated from the parity generating matrices Gp and Gq are each fixed values. Accordingly, the communication device which conforms to the second error detection method holds an added fixed value (Qa+Pa) which is calculated in advance and it is sufficient if the added fixed value (Qa+Pa) is normally added (that is, an exclusive OR is taken) with regard to the parity portion generated from the transmission data during frame transmission and reception. When the connection request frame is transmitted from the communication device which conforms to the second error detection method, the redundant code which is attached to the physical layer header thereof is converted to the parity Pa based on the first error detection method using the adding process of the added fixed value (Qa+Pa) and it is possible to ensure upward compatibility.

On the other hand, even if the added fixed value (Qa+Pa) is added to a parity (which is provisionally set as Qa″) which is calculated with regard to transmission data A′ other than the physical layer header of the connection request frame, it is not converted into redundant code which ensures upward compatibility. If an arrangement is introduced (as will be described later) where the error correction method which is applied by a communication counterpart is confirmed when establishing a connection, after the establishing of a connection is completed, if error detection code is generated and examined using an error detection method which corresponds to the communication counterpart, it is possible to ensure the upward compatibility with the communication device which follows the first error detection method.

In addition, when the communication device which conforms to the second error detection method receives transmission data A′ other than the physical layer header of the connection request frame, if the added fixed value (Qa+Pa) is added to the attached redundant code (that is, an exclusive OR is taken), inverse conversion to the original parity Qa″ is possible and it is possible to correctly perform error detection processing using the second error detection method.

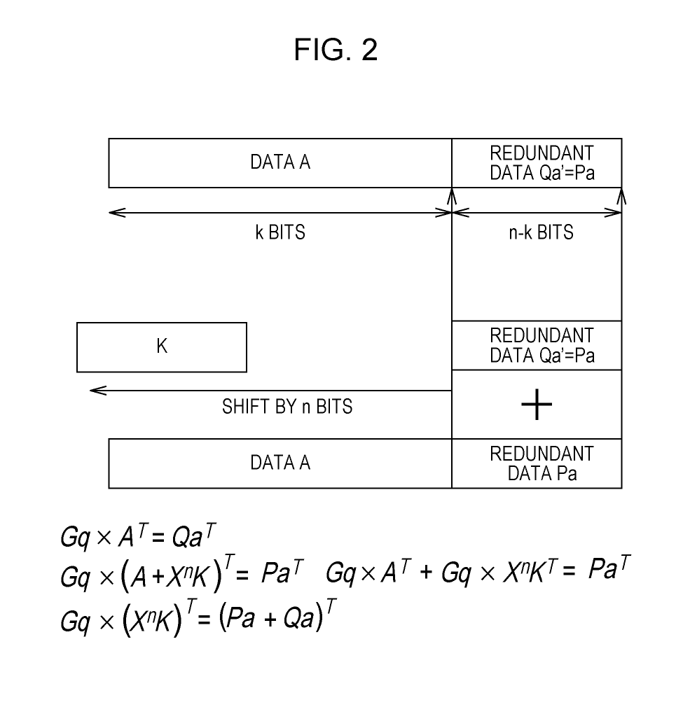

In FIG. 2, a modified example of a method is shown where a code word which is generated using the second error detection method is converted to error detection code which ensures upward compatibility with the first error detection method.

In FIG. 2, data K is a fixed value where a bit position of the original transmission data A is shifted from a least significant bit to a higher order by n bits and is represented by XⁿK. Then, when the parity generating matrix Gq is multiplied with regard to the fixed value K which is bit-shifted by n bits, the fixed value K is determined so that it is possible to generate the added fixed value (Qa+Pa). The representation of the determination of the fixed value K using an equation is as shown in equation (3).

Gq×(XⁿK)^{T}=(Pa+Qa)^{T} (3)

In this case, the fixed value K where the bit position is shifted by n bits is added to the data A (an exclusive OR is taken) and then multiplied by the parity generating matrix Gq, it is possible to obtain the redundant code Pa which ensures upward compatibility with the first error detection method as shown in equation (4).

Gq×(A+XⁿK)^{T}=Pa^{T}

Gq×A^{T}+Gq×XⁿK^{T}=Pa^{T} (4)

Accordingly, it is sufficient if the communication device which conforms to the second error detection method holds the fixed value K and a bit-shifting number n instead of holding the added fixed value (Qa+Pa) which is to be added to the parity portion and conversion of the redundant data is performed using the calculation shown in equation (4). In addition, when receiving, it is sufficient if the communication device which conforms to the second error detection method performs error detection or error detection correction after adding the fixed value K where the bit position is shifted by n bits to the received data (after taking an exclusive OR).

Here, it is possible to determine the fixed value K by multiplying an inverse matrix Gq⁻¹ of the parity generating matrix Gq to both side of equation (3). The fixed value K differs according to the bit position n which is shifted, but in any case, the fixed value K is selected so as the parity becomes Qa+Pa.

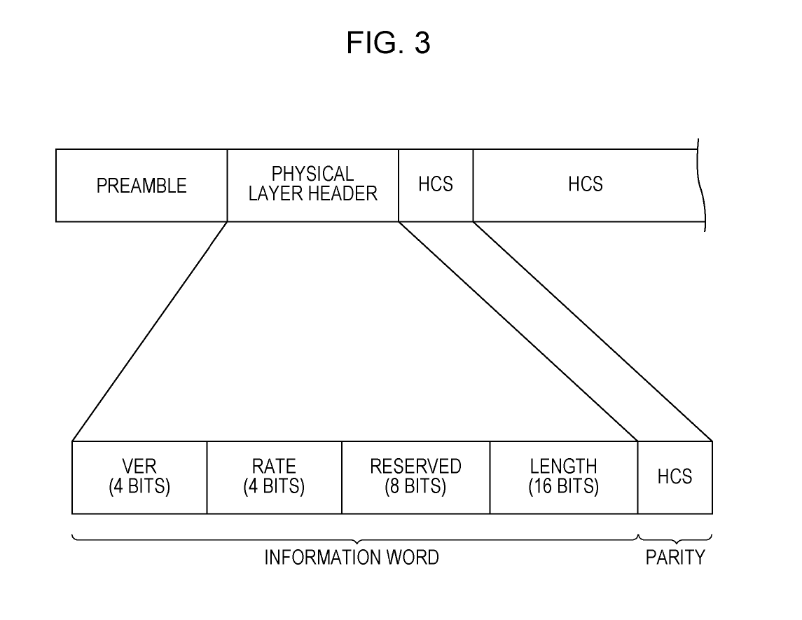

In FIG. 3, one example is shown of a frame format used in a communication system.

The frame in FIG. 3 has a configuration where a physical layer payload continues after a preamble, a physical layer header (PHY Header), and a header check sequence (HCS) with regard to the physical layer header.

The preamble is used mainly in package detection, synchronous acquisition, or the like at a side receiving a frame. In the physical layer header, various types of control information and setting information in regard to the physical layer is written. In the example shown in the diagram, the physical layer header is a field with a total of 32 bits formed from a field (Ver) with a four bit length where version information of the communication method is written, a field (Rate) with a four bit length where a communication rate is written, a reservation field (Reserved) with an eight bit length, and a field (Length) with a 16 bit length where information relating to the length of a payload which follows is written.

In the header check sequence (HCS), a code word, which is generated in accordance with either the first error detection method or the second error detection method, is stored. Specifically, for the first error detection method (ECS), error detection code with a 16 bit length, which is obtained by multiplying the parity generating matrix Gp with a data string of the physical layer header with a 32 bit length as an information word of the coding target, is stored. In addition, for the second error detection method (CRC), a code word with a 16 bit length, which is obtained by multiplying the parity generating matrix Gp with a data string of the physical layer header with a 32 bit length, and an error detection code with a 16 bit length attached to the added fixed value (described above) are stored.

In a specific management frame such as a connection request frame, since the payload length is constant (or there is no payload), the descriptive content of the physical layer header, that is, the bit string, is a constant value at the same communication rate.

When the communication device which adopts the second error detection method and which ensures upward compatibility with the first error detection method transmits a frame in a “compatibility mode” which corresponds to both the first error detection method and the second error detection method, after the parity is generated by the parity generating matrix Gq being multiplied with regard to the data string which configures the physical layer header, by adding the parity to the added fixed value Qa+Pa (by taking an exclusive OR), the header check sequence is generated (refer to FIG. 1B). Or, it is possible to generate the header check sequence even by adding K where the bit position is shifted by n bits to the data string which configures the physical layer header and multiplying by the parity generating matrix Gq (refer to FIG. 2). In addition, when a frame is transmitted in a “lower order mode” which corresponds to only the first error detection method, the header check sequence is generated by multiplying the parity generating matrix Gp with regard to the data string which configures the physical layer header.

Here, the configuration of the physical layer payload and the method of generating error detection code in the physical layer payload is not directly related to the concept of the disclosure and the details are omitted in FIG. 3.

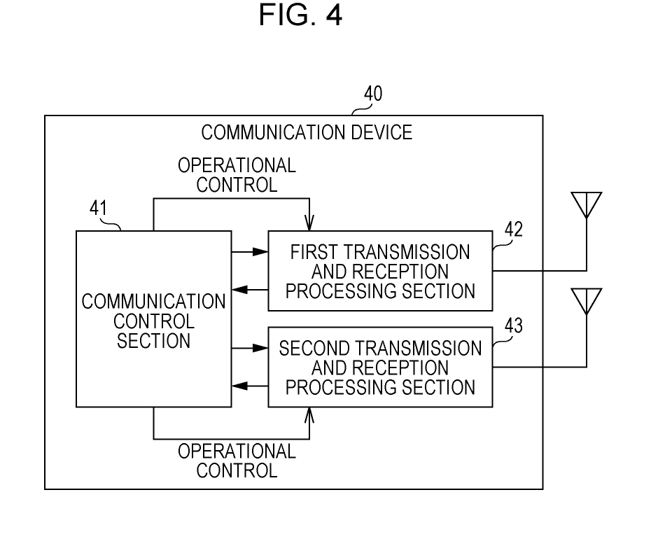

FIG. 4 schematically illustrates a configuration example of a communication device which adopts the second error detection method and ensures upward compatibility with the first error detection method (and which is equivalent to a higher order model).

A communication device 40 in FIG. 4 is provided with a communication control section 41, a first transmission and reception processing section 42, and a second transmission and reception processing section 43.

The first transmission and reception processing section 42 performs generating and checking of error detection code in accordance with the first error detection method as well as performing digital processing such as modulation or demodulation and coding decryption of transmission data, AD conversion and DA conversion of transmission and reception signals, and RF processing such as up-conversion of transmission signals to an RF band or down-conversion of received signals.

In addition, the second transmission and reception processing section 43 performs generating and checking of error detection code in accordance with the second error detection method as well as performing digital processing such as modulation or demodulation and coding decryption of transmission data, AD conversion and DA conversion of transmission and reception signals, and RF processing such as up-conversion of transmission signals to an RF band or down-conversion of received signals.

Here, it is possible to implement a portion of circuitry of a modulation and demodulation circuit, a coding decryption circuit, a RF processing circuit, and the like together using the first transmission and reception processing section 42 and the second transmission and reception processing section 43. In addition, the first transmission and reception processing section 42 and the second transmission and reception processing section 43 may be provided with individual transmission and reception antennas or may have a shared antenna.

The communication control section 41 performs processing of transmission and reception data, control of the communication sequence, operational control of the first transmission and reception processing section 42 and the second transmission and reception processing section 43 in accordance with communication sequence, and the like. For example, the communication control section 41 controls so that a specific management frame such as the connection request frame is transmitted using the second transmission and reception processing section 43. In addition, the communication control section 41 may stop the operation of either of the transmission and reception processing sections 42 and 43 which is not used in the sequence for establishing a connection after determining the error detection method which is applied by the communication counterpart.

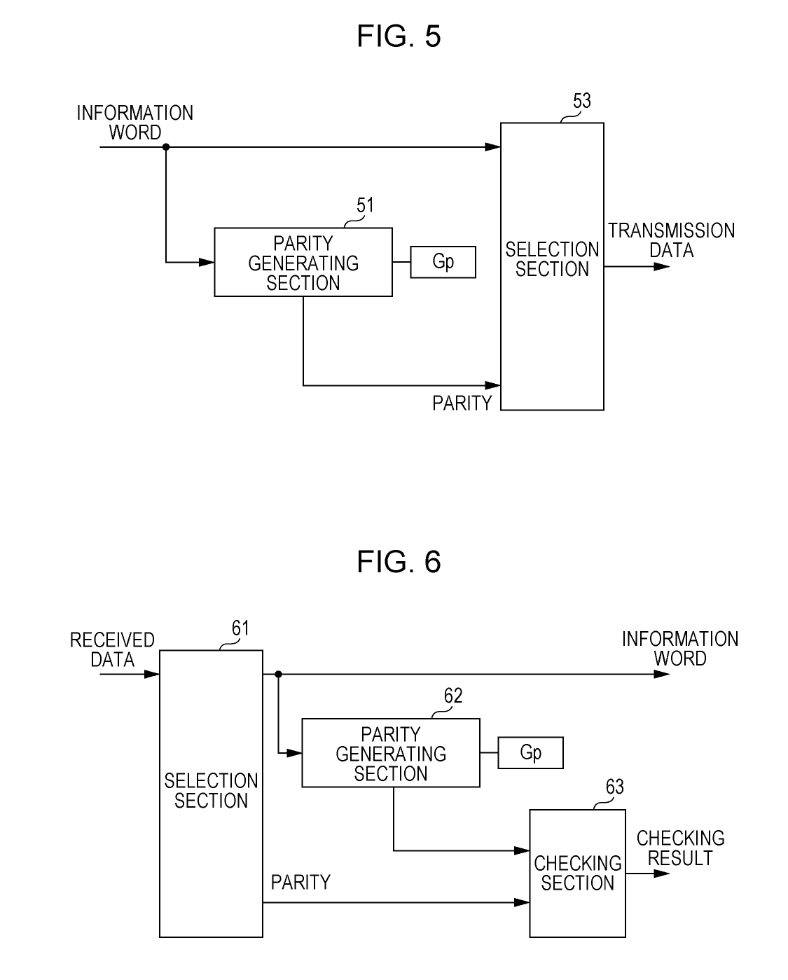

FIG. 5 schematically illustrates a functional configuration of a code generating device (ECS) for generating error detection code in accordance with the first error correction method in the first transmission and reception processing section 42.

A parity generating section 51 is provided with the parity generating matrix Gp and generates the parity with a predetermined code word length when a bit string in an information word (transmission data) is input by multiplying the bit string with Gp.

A selection section 53 initially outputs a bit string in an information word when an information word and a parity which is generated by the parity generating section 51 is input, and when the inputting is completed, next, outputs the parity. As a result, it is possible to obtain transmission data where the parity is bit-connected to the information word.

In addition, FIG. 6 schematically illustrates a functional configuration of a code generating device (ECS) for checking error detection code in accordance with the first error correction method in the first transmission and reception processing section 42.

A selection section 61 divides the received data into an information word and a parity, and selects and outputs.

A parity generating section 62 is provided with the parity generating matrix Gp and generates the parity with a predetermined code word length when a bit string in an information word (transmission data) is input from the selection section 61 by multiplying the bit string with Gp.

When the parity which is generated by the parity generating section 62 and the parity which is selected and output from the selection section 61 are input, a checking section 63 compares both parities and checks whether an error has been generated in the information word based on whether the parities match.

Then, as the code checking device in the diagram, the information word and the examination result are output.

In addition, FIG. 7 schematically illustrates a functional configuration of a code generating device (CRC) for generating error detection code which is compatible with the first error detection method in the second transmission and reception processing section 43.

A parity generating section 71 is provided with the parity generating matrix Gq and initially generates the parity with a predetermined code word length when a bit string in an information word (transmission data) is input by multiplying the bit string with Gq.

Next, a parity conversion section 72 stores the added fixed value Qa+Pa in advance and adds the added fixed value Qa+Pa to the parity which is generated by the parity generating section 71 (an exclusive OR is taken).

Or, without waiting for the parity conversion section 72, the parity generating section 71 is provided with the fixed value K described above along with the parity generating matrix Gq, and when a bit string of the information word (transmission data) is input, K where the bit position is shifted by n bits is added to the bit string and multiplied by the parity generating matrix Gq.

A selection section 73 initially outputs a bit string in an information word when an information word and a parity which is generated by the parity conversion section 72 is input, and when the inputting is completed, next, outputs the parity. As a result, it is possible to obtain transmission data where the parity is bit-connected to the information word.

Here, in a specific management frame such as the connection request frame, since the payload length is constant (or there is no payload), the descriptive content of the physical layer header, that is, the bit string, is a constant value at the same communication rate (as described above).

The added fixed values Qa and Pa are respectively parities which are generated using the respective parity generating matrices Gq and Gp with the physical layer header of the connection request frame as the information word. Accordingly, in the case where the physical layer header of the connection request frame is the information word, by adding the added fixed value Qa+Pa to the parity which is generated by the parity generating section 71 (an exclusive OR is taken), the parity is converted to the same parity as the code generating device shown in FIG. 5. In other words, the code generating device shown in FIG. 7 is able to generate a header check sequence (that is, a header check sequence where correct error detection is possible even with the code generating device shown in FIG. 6) with compatibility with the first error detection method in regard to the physical layer header of the connection request frame.

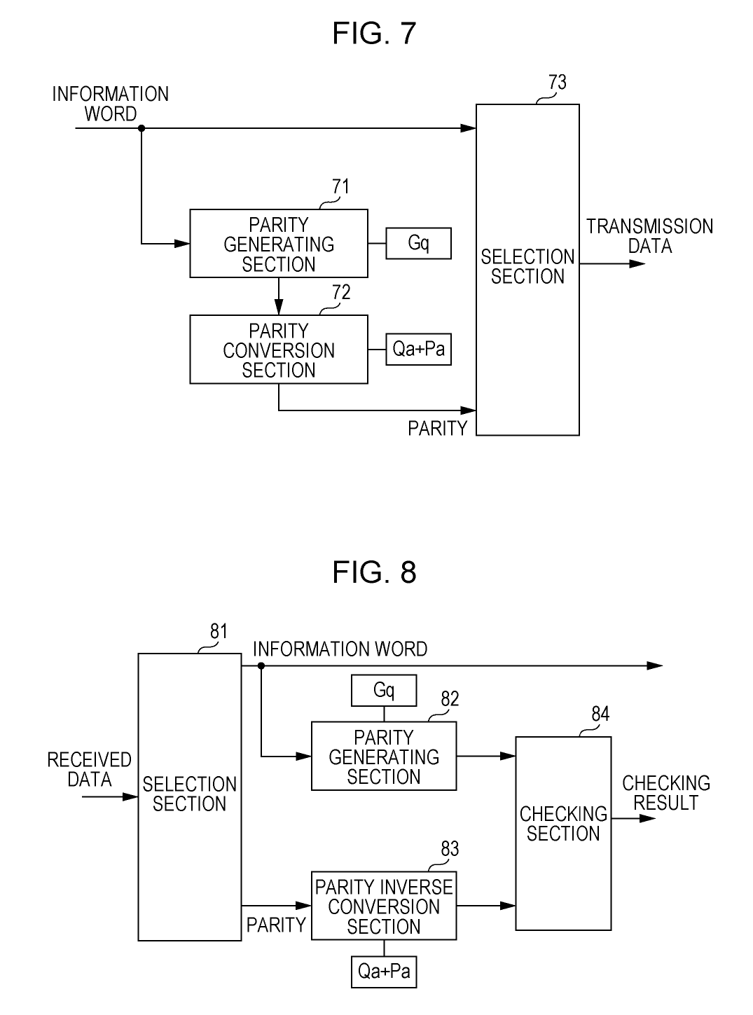

In addition, FIG. 8 schematically illustrates a functional configuration of a code generating device (CRC) for checking error detection code which is generated using the code generating device shown in FIG. 7 in the second transmission and reception processing section 43.

A selection section 81 divides the received data into an information word and a parity, and selects and outputs.

A parity generating section 82 is provided with the parity generating matrix Gq and generates the original parity with a predetermined code word length when a bit string in an information word is input from the selection section 81 by multiplying the bit string with Gq.

On the other hand, a parity inverse conversion section 83 stores the added fixed value (Qa+Pa) in advance and adds the added fixed value Qa+Pa to the parity which is selected and output from the selection section 81 (an exclusive OR is taken). When generating the error detection code, a conversion process is carried out where the added fixed value (Qa+Pa) is further added to the parity which is obtained by multiplying the parity generating matrix Gq with the original information word. Accordingly, in the parity inverse conversion section 83, it is possible to reproduce the parity before the conversion, that is, the original parity, by multiplying the input parity with the added fixed value (Qa+Pa).

Or, the parity inverse conversion section 83 is provided with the fixed value K instead of the added fixed value (Qa+Pa) and it is possible to reproduce the parity before the conversion, that is, the original parity, by adding the parity which is selected and output from the selection section 81 to a result of multiplying the parity generating matrix Gq to the fixed value K where the bit position is shifted from a least significant bit to a higher order by n bits.

When the parity which is generated from the information word input by the parity generating section 82 and the parity after inverse conversion by the parity inverse conversion section 83 are input, a checking section 84 compares both parities and checks whether an error has been generated in the information word based on whether the parities match.

Then, as the code checking device in the diagram, the information word and the examination result are output.

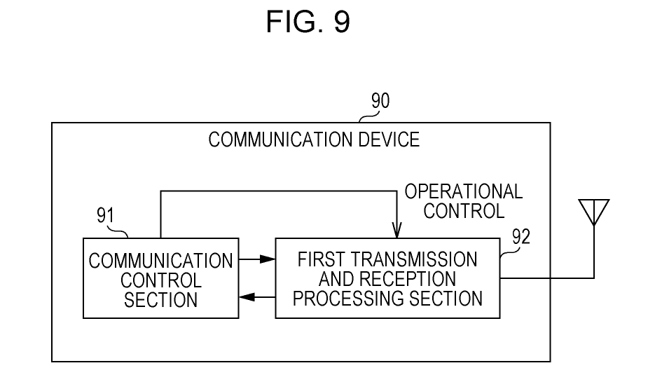

FIG. 9 schematically illustrates a configuration example of a communication device which adopts the first error detection method (equivalent to an existing model).

A communication device 90 in FIG. 9 is provided with a communication control section 91 and a first transmission and reception processing section 92.

The first transmission and reception processing section 92 performs generating and checking of error detection code in accordance with the first error detection method as well as performing digital processing such as modulation or demodulation and coding decryption of transmission data, AD conversion and DA conversion of transmission and reception signals, and RF processing such as up-conversion of transmission signals to an RF band or down-conversion of received signals.

In addition, the communication control section 91 performs processing of transmission and reception data, control of the communication sequence, operational control of the first transmission and reception processing section 92 in accordance with communication sequence, and the like.

The first transmission and reception processing section 92 is provided with a functional configuration which performs generating and checking of error detection code in accordance with the first error detection method and the sections are as already has been described while referencing FIGS. 5 and 6.

Next, a communication sequence between communication devices which adopt the second error detection method (refer to FIG. 4) and a communication sequence between a communication device which adopts the second error detection method (refer to FIG. 4) and a communication device which adopts the first error detection method (refer to FIG. 9) will be described.

In either of the combinations of the communication devices, a communication sequence is performed where a connect between the communication devices is established by one of the communication devices transmitting a connection request frame C-Req (Connection Request) which is a management frame and the other communication device displaying an intent of receiving the connection request by replying with a connection request acceptance frame C-Acc (Connection-Acceptance) which is another management frame. The communication device which transmits the connection request frame is equivalent to, for example, an initiator which operates actively and the communication device which replies with the connection request acceptance frame is equivalent to, for example, a responder which operates passively.

When the communication device which adopts the second error detection method (refer to FIG. 4) receives each of the management frames C-Req and C-Acc, “0x0” is written in the reservation region of the physical layer header when a connection using the first error detection method is requested and “0x1” is written in the reservation region of the physical layer header when a connection using the second error detection method is requested. In addition, in a case where the first error detection method and the second error detection method are adopted, the descriptive content of the physical layer header in the C-Req frame is shown in the table below.

TABLE 1

| | Ver | Rate | Reserved | Length | HCS |
|---|---|---|---|---|---|
| First Error | 0x1 | 0x1 | 0x0 | 0x0052 | 0x700b |
| Detection | | | | | |
| Method | | | | | |
| Second Error | 0x1 | 0x1 | 0x1 | 0x0052 | 0x700b |
| Detection | | | | | |
| Method | | | | | |

In a case where either the first error detection method or the second error detection method is adopted, since the descriptive content of the physical layer header is the same, the header check sequence, which is generated using either the first error detection method or the second error detection method, has the same values. In addition, in a case where the header check sequence is generated using the second error detection method, the added fixed value is attached to the parity generated using the parity generating matrix Gq and converted to a values “0x2003” and “0x700b(0xA54E) which are compatible with the first error detection method.

When the communication device which adopts the second error detection method (refer to FIG. 4) is waiting to receive either of the respective management frames of C-Req or C-Acc, the communication control section 41 operates the first transmission and reception processing section 42 and the second transmission and reception processing section 43 at the same time. Then, when either of the respective management frames of C-Req or C-Acc is received, along with the establishing of a connection, the operation of the first transmission and reception processing section 42 and the second transmission and reception processing section 43 are controlled in the following communication in accordance with the error detection method which is shown using the reservation region in the physical layer header. That is, in a case where “0x0” is written in the reservation region of the physical layer header of the received C-Req or C-Acc frame, the communication control section 41 performs the following communication with the setting of generating the header check sequence using the first error detection method (ECS). On the other hand, in a case where “0x1” is written in the reservation region of the physical layer header of the received C-Req or C-Acc frame, the communication control section 41 perform the following communication with the setting of generating the header check sequence using the second error detection method (CRC).

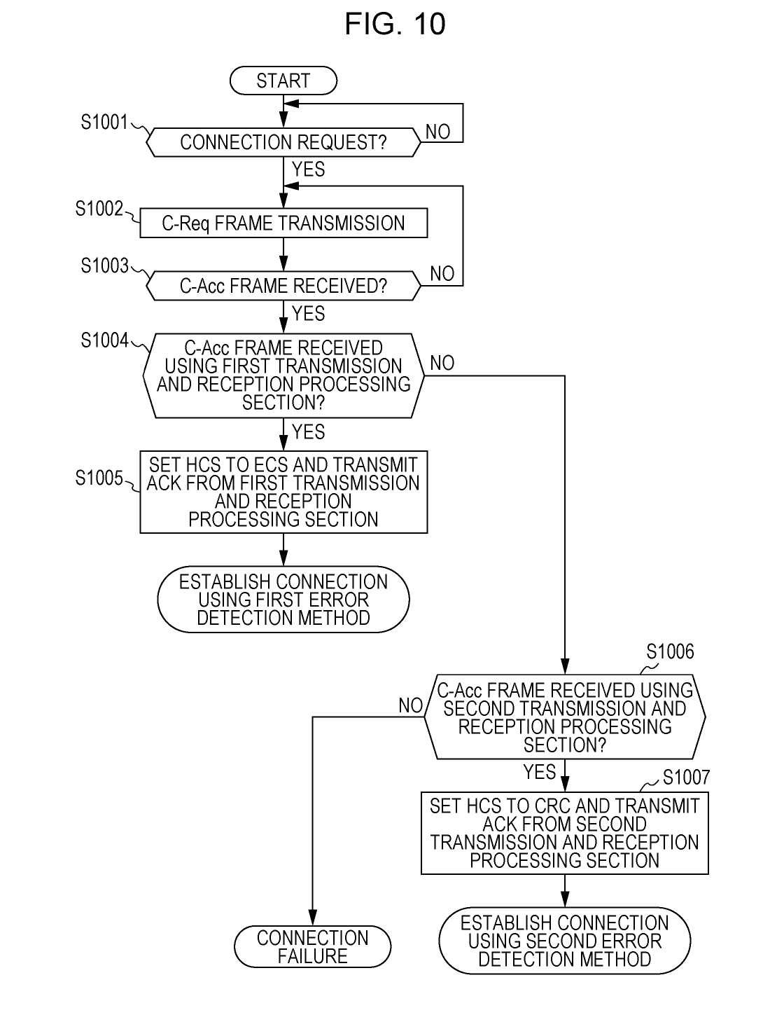

In FIG. 10, a process sequence, which is executed when the communication device which adopts the second error detection method (refer to FIG. 4) requests connection with regard to a periphery communication device, is shown in a flowchart format. The communication device which requests a connection is equivalent to, for example, an initiator which operates actively, and on the other hand, the periphery communication is equivalent to, for example, a responder which operates passively.

When a connection request is generated such as generation of transmission data with a higher order protocol such as an application (Yes in step S1001), the communication device transmits the connection request frame C-Req from the second transmission and reception processing section 43 so as to establish a connection with a data transmission destination (step S1002). At this time, in the reservation region of the physical layer header in the C-Req frame, “0x1” is written so as to request a connection using the second error detection method and the header check sequence of the physical layer header is generated in accordance with the second error detection method.

Then, after the connection request frame C-Req is transmitted, the communication device waits to receive the connection request acceptance frame C-Acc which is transmitted from the communication counterpart (step S1003). During the period of waiting for reception, the communication control section 41 operates the first transmission and reception processing section 42 and the second transmission and reception processing section 43 at the same time.

Here, when it is not possible to receive the C-Acc frame (or when no signal is received) even after waiting for reception for a predetermined period (No in step S1003), the sequence returns to step S1002 and the C-Req frame is resent. However, when the number of times of resending reaches a predetermined value, the communication device which is the connection request origin may give up on the connection and end the process routine.

As described above, the header check sequence of the C-Req frame which is transmitted in accordance with the second error detection method has compatibility with the first error detection method. As a result, when the C-Acc frame was able to be received (Yes in step S1003), there is a possibility that the transmission origin is either the communication device which adopts the first error detection method or the communication device which adopts the second error detection method.

When any signal is received, for example, a reception processing section in the first transmission and reception processing section 42 is attempted (step S1004). If the communication device which adopts the first error detection method is the transmission origin of the C-Acc frame, the first transmission and reception processing section 42 performs reception and an error is not detected by checking using the first error detection method (Yes in step S1004). In this case, in the communication device which is the connection request origin, when it is further confirmed that “0x0” is written in the reservation region in the physical layer header of the received C-Acc frame, the communication control section 41 transmits an ACK frame (step S1005) using the first transmission and reception processing section 42 with the setting of the header check sequence being generated using the first error detection method (ECS) and establishes a connection which uses the first error detection method. In the reservation region in the physical layer header of the ACK frame, “0x0” is written. After the establishing of the connection, the operation of the second transmission and reception processing section 43 may be stopped.

On the other hand, when the transmission origin of the C-Acc frame is not the communication device which adopts the first error detection method, the C-Acc frame is not able to be received by the first transmission and reception processing section 42 or an error is detected by checking using the first error detection method (No in step S1004). In this case, instead, a reception processing section in the second transmission and reception processing section 43 is attempted (step S1006).

If the second transmission and reception processing section 43 receives the C-Acc frame and an error is not detected by checking using the second error detection method (Yes in step S1006), it is possible to determine that the transmission origin of the C-Acc frame is the communication device which adopts the second error detection method. In this case, in the communication device which is the connection request origin, when it is further confirmed that “0x1” is written in the reservation region in the physical layer header of the received C-Acc frame, the communication control section transmits an ACK frame (step S1007) using the second transmission and reception processing section 43 with the setting of the header check sequence being generated using the second error detection method (CRC) and establishes a connection which uses the second error detection method. In the reservation region in the physical layer header of the ACK frame, “0x1” is written. After the establishing of the connection, the operation of the first transmission and reception processing section 42 may be stopped.

In addition, when both of the first transmission and reception processing section 42 and the second transmission and reception processing section 43 which are waiting for reception fail in the process of receiving the C-Acc frame or errors are detected (No in step S1006), the process ends as connection has failed.

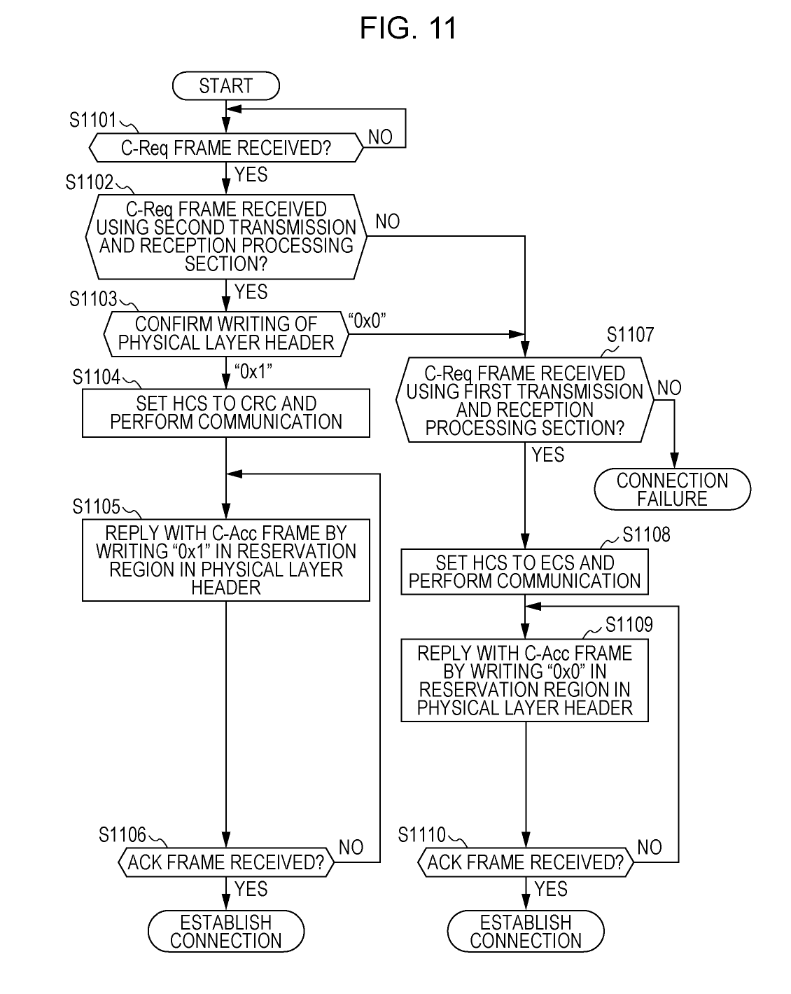

In addition, in FIG. 11, a process sequence, which is executed when the communication device which adopts the second error detection method (refer to FIG. 4) receives a connection request frame from the periphery communication device, is shown in a flowchart format. The communication device which requests a connection is equivalent to, for example, an initiator which operates actively, and on the other hand, the periphery communication is equivalent to, for example, a responder which operates passively (in the same manner as above).

The communication device waits for reception of the connection request frame C-Req which is transmitted from the periphery communication device (No in step S1101). During the period of waiting for reception, the communication control section 41 operates the first transmission and reception processing section 42 and the second transmission and reception processing section 43 at the same time and both of the transmission and reception processing sections are waiting for reception.

As described above, the header check sequence of the C-Req which is transmitted in accordance with the second error detection method is compatible with the first error detection method. As a result, it is possible to perform error detection by the C-Req frame to be received by both the first transmission and reception processing section 42 and the second transmission and reception processing section 43 which are waiting for reception at the same time. In addition, there is a possibility that the transmission origin of the C-Req frame is either the communication device which adopts the first error detection method or the communication device which adopts the second error detection method.

When the C-Req frame (or any signal) arrives from the communication counterpart (Yes in step S1101), initially, reception and an error detection process using the second transmission and reception processing section 43 is attempted (step S1102).

If the second transmission and reception processing section 43 receives the C-Req frame and an error is not detected by checking using the second error detection method (Yes in step S1002), the communication device which is the connection request destination confirms the descriptive content of the physical layer header (step S1103).

Here, in a case where “0x1” is written in the reservation region in the physical layer header of the received C-Req frame (“0x1” in step S1003), the communication control section 41 performs communication (step S1104) hereinafter using the second transmission and reception processing section 43 with the setting of the header check sequence being generated using the second error detection method (CRC). In this case, the operation of the first transmission and reception processing section 42 may be stopped.

Next, the communication device which is the connection request destination generates an C-Acc frame by writing “0x1” in the reservation region in the physical layer header and creating a header check sequence using the second error detection method and there is a reply with the C-Acc frame from the second transmission and reception processing section 43 to the communication device which is the connection request origin (step S1105). Then, after having replied with the C-Acc frame, if an ACK frame is able to be received using the second transmission and reception processing section 43 from the connection request origin within a predetermined period (Yes in step S1106), a connection is established which uses the second error detection method. When the ACK frame is received, it is confirmed that “0x1” is written in the reservation region in the physical layer header.

In addition, when the communication device which is the connection request destination is not able to receive the ACK frame from the connection request origin within a predetermined period from the transmitting of the C-Acc frame (No in step S1106), the sequence returns to step S1105 and the C-Acc frame is resent. However, when the number of times of resending reaches a predetermined value, the communication device which is the connection request destination may give up on the connection and end the process routine.

On the other hand, when the C-Req frame is not able to be received by the second transmission and reception processing section 43 or an error is detected by checking using the second error detection method (No in step S1102), or in a case where “0x0” is written in the reservation region in the physical layer header of the received C-Req frame (“0x0” in step S1103), next, reception and an error detection process using the first transmission and reception processing section 42 is attempted (step S1107).

When the C-Req frame is not able to be received by the first transmission and reception processing section 42 or an error is detected by checking using the first error detection method (No in step S1107), the process ends as connection has failed.

In addition, when the C-Req frame is received using the first transmission and reception processing section 42 and an error is not detected by checking using the first error detection method (Yes in step S1107), the communication control section 41 performs communication (step S1108) hereinafter using the first transmission and reception processing section 42 with the setting of the header check sequence being generated using the first error detection method (ECS). In this case, the operation of the second transmission and reception processing section 43 may be stopped.

Next, the communication device which is the connection request destination generates an C-Acc frame by writing “0x0” in the reservation region in the physical layer header and creating a header check sequence using the first error detection method and there is a reply with the C-Acc frame from the first transmission and reception processing section 42 to the communication device which is the connection request origin (step S1109). Then, after having replied with the C-Acc frame, if an ACK frame is able to be received using the first transmission and reception processing section 42 from the connection request origin within a predetermined period (Yes in step S1110), a connection is established which uses the first error detection method.

In addition, the communication device which is the connection request destination is not able to receive the C-Acc frame from the connection request origin within a predetermined period from the transmitting of the C-Acc frame (No in step S1110), the sequence returns to step S1009 and the C-Acc frame is resent. However, when the number of times of resending reaches a predetermined value, the communication device which is the connection request destination may give up on the connection and end the process routine.

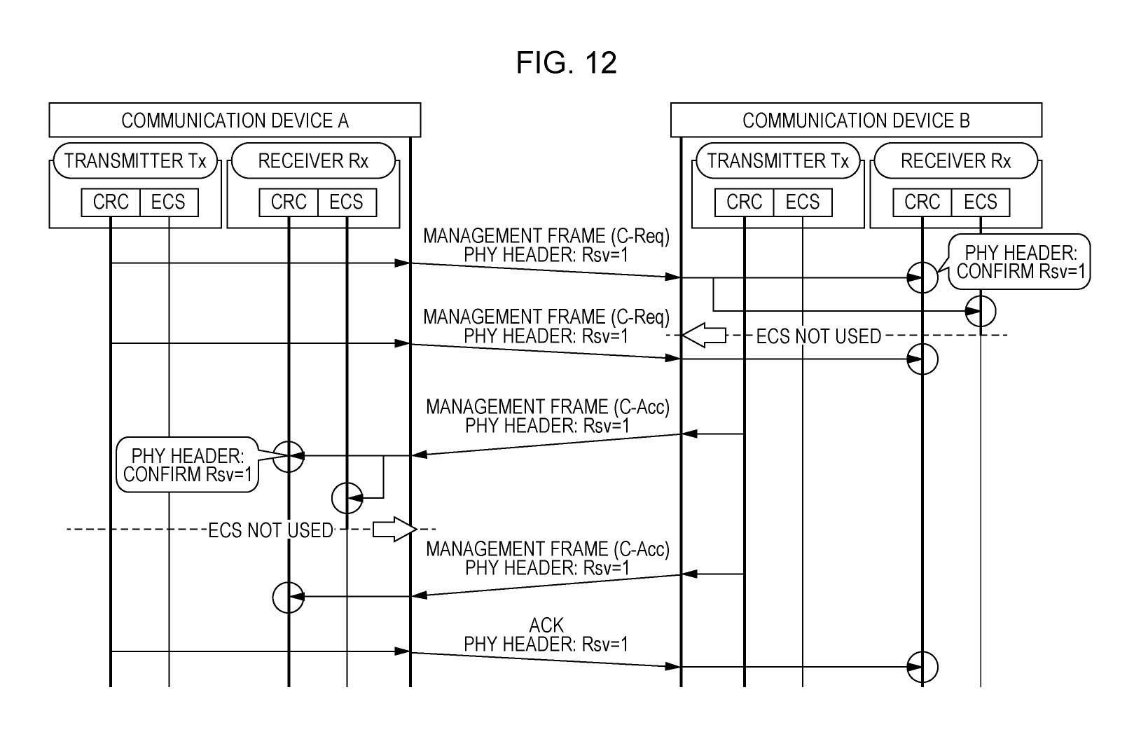

FIG. 12 illustrates a communication sequence example for establishing a connection between the (new models of) communication devices (refer to FIG. 4) which adopt the second error detection method and ensure upward compatibility with the first error detection method. In FIG. 12, the communication device which is the connection request origin (or the active side) is the “communication device A” and the communication device which is the connection request destination (or the passive side) is the “communication device B”. In addition, in each of the communication devices A and B, transmitters are represented by “Tx” and receivers are represented by “Rx”, and in each of the transmitters and receivers, functional blocks equivalent to the first transmission and reception processing sections 42 are represented by “ECS” and functional blocks equivalent to the second transmission and reception processing sections 43 are represented by “CRC”. In addition, the periods where each of the functional blocks is operating are represented by solid lines.

The communication device A and the communication device B operate the CRC of the transmitters Tx and operate the CRC and the ECS of the receivers Rx at the same time when waiting for reception.

The communication device A transmits a C-Req frame from the CRC of the transmitter Tx by writing “0x1” in the reservation region of the physical layer header so as to request a connection using the second error detection method. The header check sequence at this time is generated using the code generating device shown in FIG. 7.

At this time, the communication device B operates both the CRC and the ECS of the receiver Rx. The header check sequence generated using the code generating device shown in FIG. 7 is able to detect errors in either of the code detection devices shown in FIG. 6 or 8. That is, at the side of the communication device B, it is possible to perform error detection by receiving the C-Req frame received from the communication device A using either the CRC or the ECS of the receiver Rx.

Here, when the communication device B decrypts the received C-Req frame and confirms that “0x1” is written in the reservation region of the physical layer header in the CRC of the receiver Rx, it is determined that communication is performed hereinafter using the second transmission and reception processing section 43, and accordance to this, the ECS is not used, that is, the operation of the first transmission and reception processing section 42 is stopped.

On the other hand, at the side of the communication device A, since the C-Acc frame from the communication device B is not able to be received even after waiting for reception for a predetermined period, the same C-Req frame is resent as described above.

The communication device B operates only the CRC of the receiver Rx, and when the C-Req frame which is resent by the communication device A is received using the CRC of the receiver Rx, there is a reply with a C-Acc frame from the CRC of the transmitter Tx by writing “0x1” in the reservation region of the physical layer header so as to accept the connection request using the second error detection method.

At this time, the communication device A operates both the CRC and the ECS of the receiver Rx. The header check sequence generated using the code generating device shown in FIG. 7 is able to detect errors in either of the code detection devices shown in FIG. 6 or 8. That is, at the side of the communication device A, it is possible to perform error detection by receiving the C-Acc frame received from the communication device B using either the CRC or the ECS of the receiver Rx.

Here, when the communication device A decrypts the received C-Acc frame and confirms that “0x1” is written in the reservation region of the physical layer header in the CRC of the receiver Rx, it is determined that communication is performed hereinafter using the second transmission and reception processing section 43, and accordance to this, the ECS is not used, that is, the operation of the first transmission and reception processing section 42 is stopped.

On the other hand, at the side of the communication device B, since the ACK frame from the communication device A is not able to be received even after waiting for reception for a predetermined period, the same C-Acc frame is resent as described above.

The communication device A operates only the CRC of the receiver Rx and when the C-Acc frame which is resent by the communication device B is received using the CRC of the receiver Rx, an ACK frame is transmitted from the CRC of the transmitter Tx by writing “0x1” in the reservation region of the physical layer header so as to establish a connection using the second error detection method. Then, a connection is established by the communication device B receiving the ACK frame.

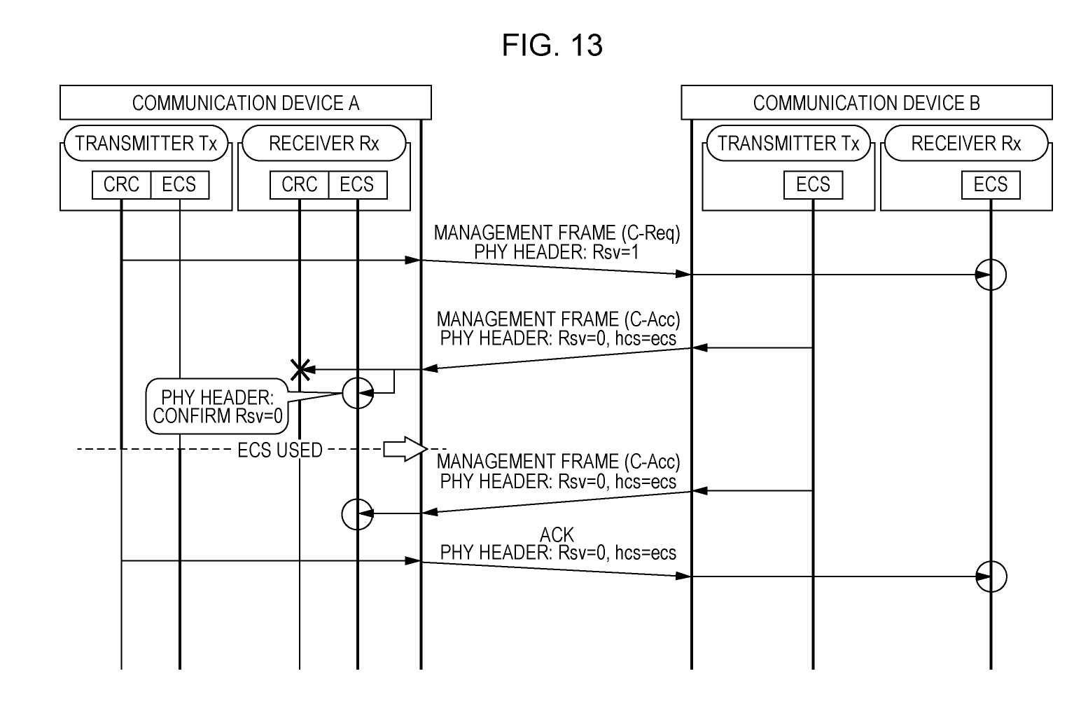

FIG. 13 illustrates a communication sequence example for establishing a connection by the (new model of) communication device (refer to FIG. 4) which adopts the second error detection method and ensures upward compatibility with the first error detection method requesting a connection with the (existing model of) communication device (refer to FIG. 9) which adopts the first error detection method. In FIG. 13, the communication device which is the connection request origin (or the active side) is the “communication device A” and the communication device which is the connection request destination (or the passive side) is the “communication device B”. In addition, in each of the communication devices A and B, transmitters are represented by “Tx” and receivers are represented by “Rx”, and in each of the transmitters and receivers, functional blocks equivalent to the first transmission and reception processing sections 42 or 92 are represented by “ECS”, and a functional block equivalent to the second transmission and reception processing section 43 is represented by “CRC”. In addition, the periods where each of the functional blocks is operating are represented by solid lines.

The communication device A operates the CRC of the transmitter Tx and operates the CRC and the ECS of the receiver Rx at the same time when waiting for reception. On the other hand, the communication device B is only provided with the ECS of the transmitter Tx and the receiver Rx and these are operated.

The communication device A transmits a C-Req frame from the CRC of the transmitter Tx by writing “0x1” in the reservation region of the physical layer header so as to request a connection using the second error detection method. The header check sequence at this time is generated using the code generating device shown in FIG. 7.

The header check sequence generated using the code generating device shown in FIG. 7 is able to detect errors in either of the code detection devices shown in FIG. 6 or 8. That is, at the side of the communication device B, it is possible to perform error detection by receiving the C-Req frame received from the communication device A using the ECS of the receiver Rx.

On the other hand, the communication device B responses to the receiving of the C-Req frame from the communication device A and replied with the C-Acc frame. Since the communication device B accepts the connection request using the first error detection method, “0x0” is written in the reservation region of the physical layer header of the C-Acc frame. In addition, the header check sequence at this time is generated using the code generating device shown in FIG. 5.

At this time, the communication device A operates both the CRC and the ECS of the receiver Rx. The header check sequence generated using the code generating device shown in FIG. 5 is able to detect errors in the code detection device shown in FIG. 6, but is not able to detect errors in the code detection device shown in FIG. 8. Accordingly, at the side of the communication device A, it is possible to perform error detection by receiving the C-Acc frame received from the communication device B using only the ECS of the receiver Rx.

Here, when the communication device A decrypts the received C-Acc frame and confirms that “0x0” is written in the reservation region of the physical layer header in the ECS of the receiver Rx, it is determined that communication is performed hereinafter using the first transmission and reception processing section 42, and accordance to this, only the ECS is used, that is, the operation of the second transmission and reception processing section 43 is stopped and the first transmission and reception processing section 42 is activated.

On the other hand, at the side of the communication device B, since the ACK frame from the communication device A is not able to be received even after waiting for reception for a predetermined period, the same C-Acc frame is resent as described above.

The communication device A operates only the ECS of the receiver Rx and when the C-Acc frame which is resent by the communication device B is received using the ECS of the receiver Rx, an ACK frame is transmitted from the ECS of the transmitter Tx by writing “0x0” in the reservation region of the physical layer header so as to establish a connection using the first error detection method. Then, a connection is established by the communication device B receiving the ACK frame.

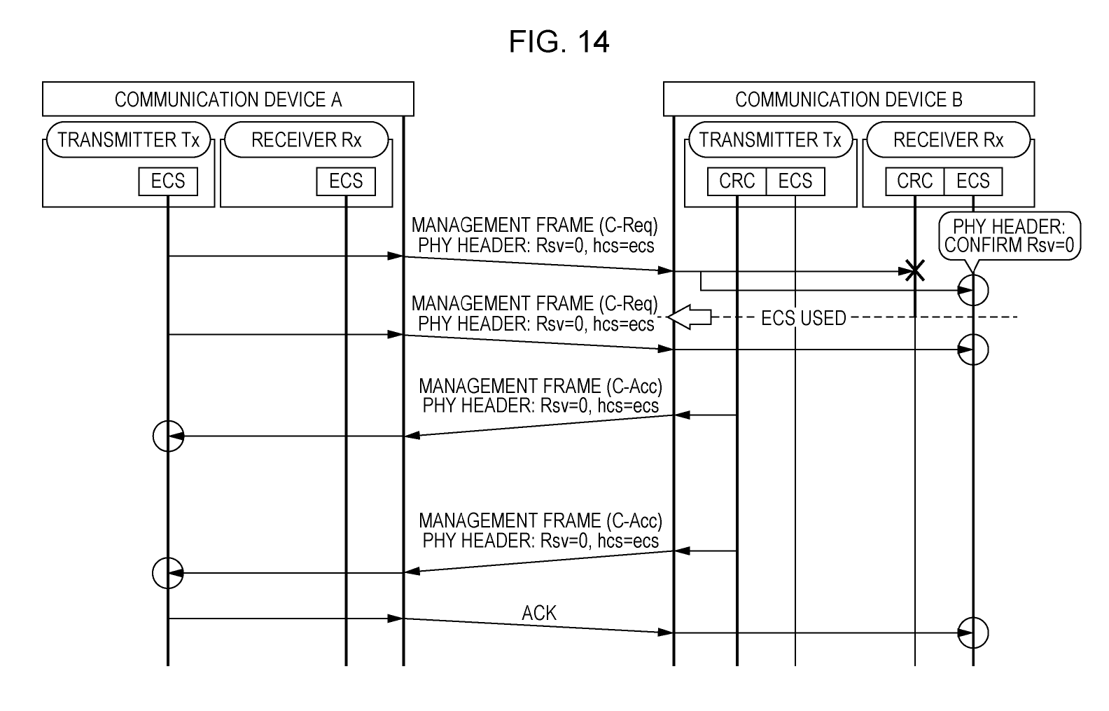

FIG. 14 illustrates a communication sequence example for establishing a connection by the (existing model of) communication device (refer to FIG. 9) which adopts the first error detection method requesting a connection with the (new model of) communication device (refer to FIG. 4) which adopts the second error detection method and ensures upward compatibility with the first error detection method. In FIG. 14, the communication device which is the connection request origin (or the active side) is the “communication device A” and the communication device which is the connection request destination (or the passive side) is the “communication device B”. In addition, in each of the communication devices A and B, transmitters are represented by “Tx” and receivers are represented by “Rx”, and in each of the transmitters and receivers, functional blocks equivalent to the first transmission and reception processing sections 42 or 92 are represented by “ECS”, and a functional block equivalent to the second transmission and reception processing section 43 is represented by “CRC”. In addition, the periods where each of the functional blocks is operating are represented by solid lines.

The communication device A is only provided with the ECS of the transmitter Tx and the receiver Rx and these are operated when waiting for reception. On the other hand, the communication device B operates the CRC of the transmitter Tx and operates the CRC and the ECS of the receiver Rx at the same time when waiting for reception.

The communication device A transmits a C-Req frame from the ECS of the transmitter Tx by writing “0x0” in the reservation region of the physical layer header so as to request a connection using the first error detection method. The header check sequence at this time is generated using the code generating device shown in FIG. 5.

The header check sequence generated using the code generating device shown in FIG. 5 is able to detect errors in the code detection device shown in FIG. 6, but is not able to detect errors in the code detection device shown in FIG. 8. Accordingly, at the side of the communication device B, it is possible to perform error detection by receiving the C-Req frame received from the communication device A using only the ECS of the receiver Rx.

Here, when the communication device B decrypts the received C-Req frame and confirms that “0x0” is written in the reservation region of the physical layer header in the ECS of the receiver Rx, it is determined that communication is performed hereinafter using the first transmission and reception processing section 42, and accordance to this, only the ECS is used, that is, the operation of the second transmission and reception processing section 43 is stopped and the first transmission and reception processing section 42 is activated.

On the other hand, at the side of the communication device A, since the C-Acc frame from the communication device B is not able to be received even after waiting for reception for a predetermined period, the same C-Req frame is resent as described above.

At this time, the communication device B operates only the ECS of the receiver Rx and when the C-Req frame from the communication device A is received, the header check sequence is checked using the code detection device shown in FIG. 6. Then, the communication device B replies with a C-Acc frame from the ECS of the transmitter Tx if an error is not detected. Since the connection request is accepted using the first error detection method, “0x0” is written in the reservation region in the physical layer header of the C-Acc frame. In addition, the header check sequence at this time is generated using the code generating device shown in FIG. 5.

In addition, when the communication device B is not able to receive an ACK frame from the communication device A even after waiting for reception for a predetermined period, the same C-Acc frame is resent as described above from the ECS of the transmitter Tx.

In the communication device A, when the C-Acc frame which is resent by the communication device B is received using the ECS of the receiver Rx, an ACK frame is transmitted from the ECS of the transmitter Tx by writing “0x0” in the reservation region of the physical layer header so as to establish a connection using the first error detection method. Then, a connection is established by the communication device B receiving the ACK frame.

In the embodiment shown in FIGS. 12 to 14, it is possible to establish a connection by setting the header check sequence with compatibility with the first error detection method using each frame of C-Req and C-Acc in the sequence for establishing a connection. In addition, it is possible to ensure upward compatibility with the first error detection method using the expressing of the error detection method in the reservation region of the physical layer header in each frame of C-Req and C-Acc (that is, writing of “0x1”) and the setting of the header check sequence with compatibility with the first error detection method.

### [First Modified Example of Sequence for Establishing Connection]

As another method for establishing a connection while ensuring upward compatibility with the first detection method, there is a method where a sequence for establishing connection is performed using only the first error detection method. In this method, in the second error detection method, a parity, which is obtained by multiplying a parity generating matrix Gq with an information word which is a coding target, is used as is as a parity and a parity conversion process as shown in FIGS. 1B and 2 is not performed. In addition, in this method, it is possible for a connection request destination to transmit a probe request frame which inquiries of the error detection method with regard to the connection request origin after a connection is established, and with regard to this, the connection request origin replies with ACK.

In addition, in this method, in each of the management frames which are used when establishing a connection such as C-Req, C-Acc, ACK, and the like, an error detection method which is applied to the frame is identified using a version region (Ver) in the physical layer header and whether or not there is correspondence with the second error detection method is expressed using the reservation region (Reserved). Specifically, the communication device which corresponds to both the first error detection method and the second error detection method writes “w” in the reservation region and the communication device which corresponds to only the first error detection method writes “x” in the reservation region. In addition, when setting a header check sequence which is generated in accordance with the first error detection method, “z” is written in the version region, and when setting a header check sequence which is generated in accordance with the second error detection method, “y” is written in the version region.

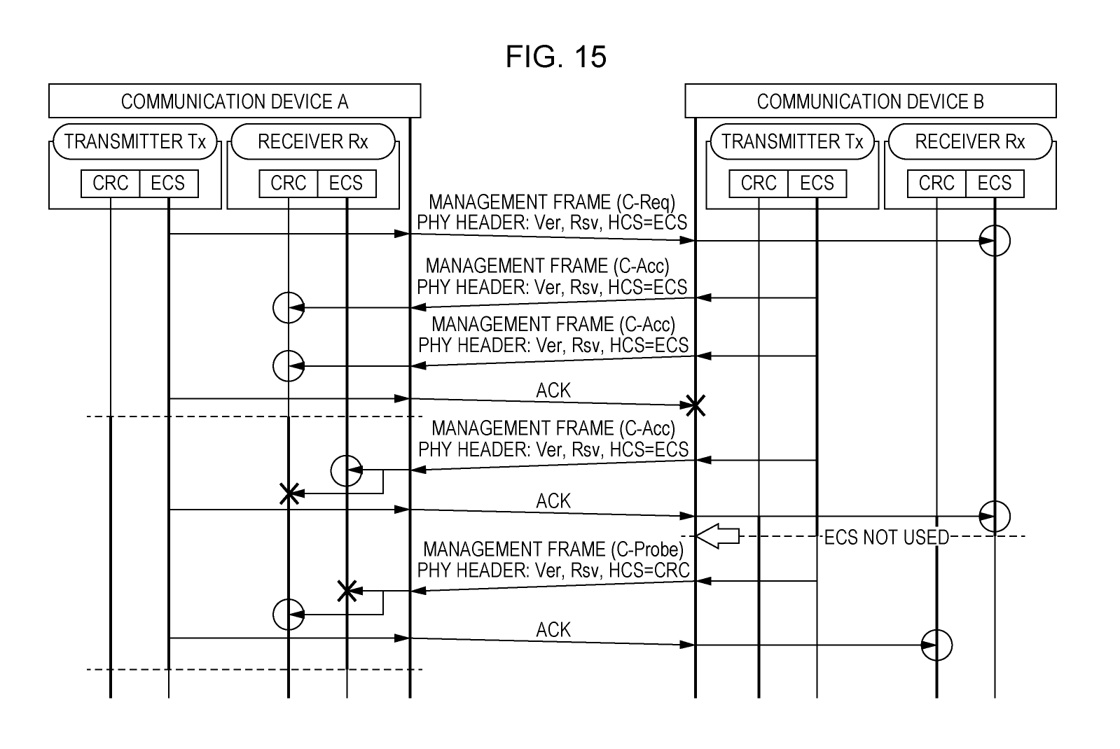

FIG. 15 illustrates a communication sequence example where this method is applied. In the communication sequence example in the diagram, a connection is established between the (new models of) communication devices (refer to FIG. 4) which adopt the second error detection method and ensure upward compatibility with the first error detection method. In FIG. 15, the communication device which is the connection request origin (or the active side) is the “communication device A” and the communication device which is the connection request destination (or the passive side) is the “communication device B”. In addition, in each of the communication devices A and B, transmitters are represented by “Tx” and receivers are represented by “Rx”, and in each of the transmitters and receivers, functional blocks equivalent to the first transmission and reception processing sections 42 are represented by “ECS” and functional blocks equivalent to the second transmission and reception processing sections 43 are represented by “CRC”. In addition, the periods where each of the functional blocks is operating are represented by solid lines.

The communication device A and the communication device B operate the ECS of the transmitters Tx and the ECS of the receivers Rx when waiting for reception.

The communication device A transmits a C-Req frame from the ECS of the transmitter Tx. In the physical layer header of the C-Req frame, the value “w”, which shows correspondence with both the first and the second error detection methods, is written in the reservation region. In addition, a header check sequence which is generated using the first error detection method is set and the value “z”, which shows the type of the header check sequence, is written in the version region of the physical layer header.

When the C-Req frame is received by the ECS of the receiver Rx, the communication device B replies with a C-Acc frame from the ECS of the transmitter Tx. In the physical layer header of the C-Acc frame, the value “w”, which shows correspondence with both the first and the second error detection methods, is written in the reservation region. In addition, a header check sequence which is generated using the first error detection method is set and the value “z”, which shows the type of the header check sequence, is written in the version region of the physical layer header.

In addition, at the side of the communication device B, since the ACK frame from the communication device A is not able to be received even after waiting for reception for a predetermined period, the same C-Acc frame is resent as described above from the ECS of the transmitter Tx.

When the communication device A decrypts the physical layer header when the C-Acc frame is received by the ECS of the receiver Rx and confirms that the value “w”, which shows correspondence with both the first and the second error detection methods, is written in the reservation region, connection using the second error detection method is determined and the use of the CRC of the transmitter Tx and the CRC of the receiver Rx, that is, the operation of the second transmission and reception processing section 43, starts. In addition, the communication device A replied with an ACK frame from the ECS of the transmitter Tx. In the physical layer header of the ACK frame, the value “w”, which shows correspondence with both the first and the second error detection methods, is written in the reservation region. In addition, a header check sequence which is generated using the first error detection method is set and the value “z”, which shows the type of the header check sequence, is written in the version region of the physical layer header.

In the example in the diagram, the communication device B failed to receive the ACK frame from the communication device A and the same C-Acc frame is resent as described above from the ECS of the transmitter Tx.

At this time, the communication device A operates both the CRC and the ECS of the receiver Rx, but since the header check sequence which is generated using the first error detection method is set with regard to the physical layer header of the C-Acc frame, reception is successful in the ECS of the receiver Rx but reception fails in the CRC of the receiver Rx. Accordingly, the communication device A replies with an ACK frame from the ECS of the transmitter Tx in the same manner as described above.

This time, the communication device B is able to receive the ACK frame from the communication device A using the ECS of the receiver Rx. Then, when the communication device B decrypts the physical layer header of the ACK frame and confirms that the value “w”, which shows correspondence with both the first and the second error detection methods, is written in the reservation region, it is confirmed that connection with the communication device A in accordance with the second error detection is possible and the use of the CRC of the transmitter Tx and the CRC of the receiver Rx, that is, the operation of the second transmission and reception processing section 43, starts. In addition, the communication device B does not use the ECS of the transmitter Tx and the ECS of the receiver Rx, that is, the operation of the first transmission and reception processing section 42 is stopped.

The communication device A confirms that a connection is established using the second error detection method by replying with the ACK frame with regard to the C-Acc frame. However, there is assumed to be situations where the ACK frame does not reach the communication device B. Therefore, here, a probe request and response sequence is applied. That is, the communication device B starts a connection confirmation sequence by transmitting a probe request frame C-Probe, which is for inquiring of the error detection method which has been decided to the communication device A, from the CRC of the transmitter Tx. In the physical layer header of the C-Probe frame, the value “w”, which shows correspondence with both the first and the second error detection methods, is written in the reservation region. In addition, a header check sequence which is generated using the second error detection method is set and the value “y”, which shows the type of the header check sequence, is written in the version region of the physical layer header.

At this time, the communication device A operates both the CRC and the ECS of the receiver Rx. The header check sequence of the C-Probe frame is set to be generated using the second error detection method. Accordingly, when the communication device A decrypts the physical layer header of the C-Probe frame and confirms that the value “z” is written in the version region, error detection processing is performed by receiving using the ECS and not the CRC of the receiver Rx.

The communication device A is able to confirm that communication is performed hereinafter in accordance with the second error detection method on the basis of the C-Probe frame which is received from the communication device B. Then, the communication device A replies with an ACK frame as a probe response from the CRC of the transmitter Tx. In the physical layer header of the ACK frame, the value “w”, which shows correspondence with both the first and the second error detection methods, is written in the reservation region. In addition, a header check sequence which is generated using the second error detection method is set and the value “y”, which shows the type of the header check sequence, is written in the version region of the physical layer header. In addition, the communication device A does not use the ECS of the transmitter Tx and the ECS of the receiver Rx, that is, the operation of the first transmission and reception processing section 42 is stopped.

On the other hand, the communication device B is able to confirm that a connection has been established in accordance with the second error detection method by receiving a probe response ACK frame from the communication device A.

In this manner, according to the communication sequence example shown in FIG. 15, a parity conversion process as shown in FIGS. 1B and 2 is not performed in the second error detection method, but the communication device which applies the second error detection method is able to establish a connection with a communication device which applies the first error detection method.

Here, in the communication sequence example shown in FIG. 15, considering that there are situations where a connection is not established since the ACK frame from the communication device A with regard to the C-Acc frame does not reach the communication device B, the communication device A replies with the ACK frame using the first error correction method when the C-Acc frame which uses the first error detection method is received and replies with the ACK frame using the second error correction method when the C-Probe frame which uses the second error detection method is received. As a result, it is necessary that the communication device A which is the connection request origin determines a process where there is dynamic switching of the error detection method and the circuitry becomes complicated.

### [Second Modified Example of Sequence for Establishing Connection]

As another method for establishing a connection while ensuring upward compatibility with the first detection method, there is a method where, in a sequence for establishing connection, a connection request frame is transmitted by the communication device which is the connection request origin applying any arbitrary error detection method and there is switching to another error detection method when frame resending reaches a time limit. In the same manner as the first modified example, in this method, in the second error detection method, a parity, which is obtained by multiplying a parity generating matrix Gq with an information word which is a coding target, is used as is as a parity and a parity conversion process as shown in FIGS. 1B and 2 is not performed.

The communication device which is the connection request origin transmits a C-Req frame by setting a header check sequence which is generated by a method of either of the first or the second error detection method. Then, when a C-Acc frame is not able to be received even if the C-Req frame is resent a predetermined number of times or a time limit has expired, it is determined that there is no correspondence with the error detection method which is being used by the communication device which is the connection request destination or the error detection method is not accepted and there is switching to another error detection method.

Here, the communication device which is the connection request origin may set a value, which is different for each error detection method, for the maximum number of times to resend the C-Req frame or the time limit. Below, the maximum number of times to resend is N or the time limit is T1 when the second error detection method is applied, and the maximum number of times to resend is M or the time limit is T2 when the first error detection method is applied.

In addition, when the communication device which is the connection request origin has received a C-Acc frame from the connection request destination, a connection is established by determining that the error detection method which is being used by the connection request destination is accepted, and hereinafter, the error detection method may be continuously used.

In addition, in each of the management frames, an error detection method which is applied to the frame is identified using a version region (Ver) in the physical layer header. That is, when setting a header check sequence which is generated in accordance with the first error detection method, “y” is written in the version region, and when setting a header check sequence which is generated in accordance with the second error detection method, “x” is written in the version region.

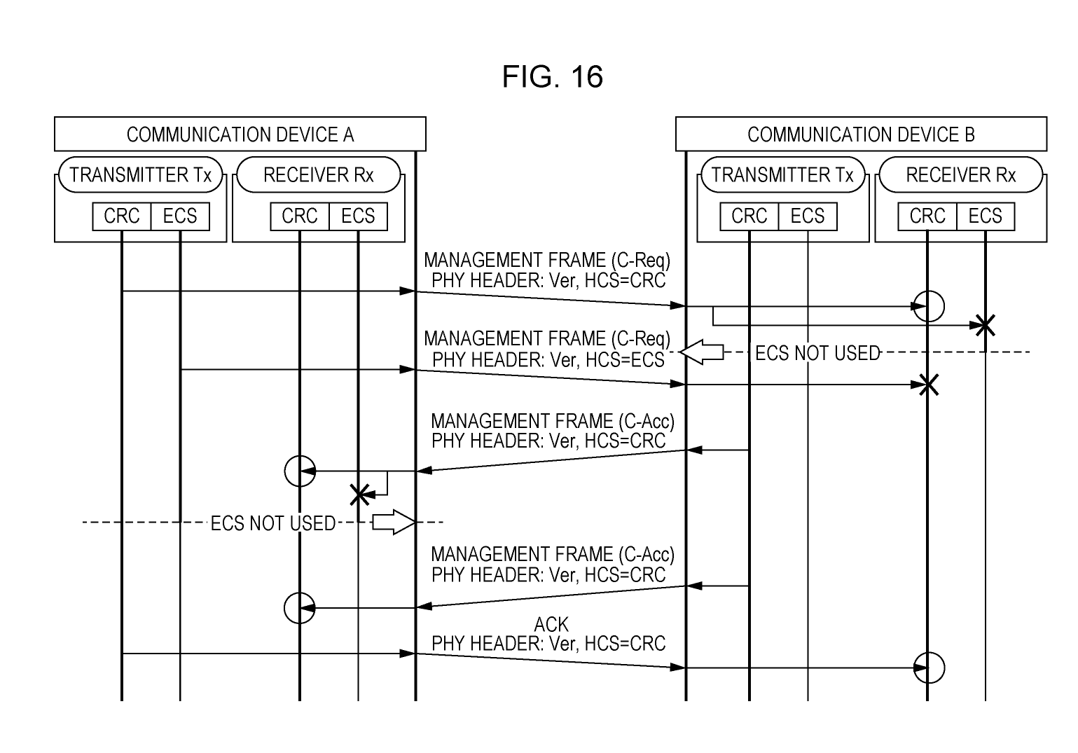

FIG. 16 illustrates a communication sequence example where an error detection method is switched when frame resending has reached a time limit. In the communication sequence example in the diagram, a connection is established between the (new models of) communication devices (refer to FIG. 4) which adopt the second error detection method and ensure upward compatibility with the first error detection method. In FIG. 16, the communication device which is the connection request origin (or the active side) is the “communication device A” and the communication device which is the connection request destination (or the passive side) is the “communication device B”. In addition, in each of the communication devices A and B, transmitters are represented by “Tx” and receivers are represented by “Rx”, and in each of the transmitters and receivers, functional blocks equivalent to the first transmission and reception processing sections 42 are represented by “ECS” and functional blocks equivalent to the second transmission and reception processing sections 43 are represented by “CRC”. In addition, the periods where each of the functional blocks is operating are represented by solid lines. In addition, in order to simplify the description, the frame resending sequence has been appropriately omitted.

The communication device A which is the connection request origin operates the CRC and the ECS of the transmitter Tx at the same time and operates the CRC and the ECS of the receiver Rx at the same time when waiting for reception. Then, the communication device A transmits the connection request C-Req frame by switching alternately between the CRC and the ECS of the transmitters Tx at a predetermined frequency. On the other hand, the communication device B which is the connection request destination operates only the CRC of the transmitter Tx and operates the CRC and the ECS of the receiver Rx at the same time when waiting for reception. When waiting for reception, the receivers Rx are made to intermittently receive.

The communication device A initially transmits a C-Req frame from the CRC of the transmitter Tx so as to request a connection using the second error correction method. With regard to the physical layer header of the C-Req frame, a header check sequence which is generated using the second error detection method is set and the value “x”, which shows that the header check sequence which is generated in accordance with the second error detection method is set, is written in the version region of the physical layer header.

At this time, the communication device B operates the CRC and the ECS of the receiver Rx. The header check sequence of the C-Req frame is set to be generated using the second error detection method. Accordingly, in the communication device B, reception is successful in the CRC of the receiver Rx but an error is detected in the header check sequence and reception fails in the ECS. Then, when the physical layer header of the C-Req frame which is received by the CRC of the receiver Rx is decrypted and it is confirmed that the value “x” is written in the version region, since the communication device B is able to recognize that the communication device A which is the connection request origin has generated the header check sequence using the second error detection method, the ECS of the receiver Rx is not used, that is, the operation of the first transmission and reception processing section 42 is stopped.

In addition, in the communication device A, when an ACK frame is not able to be received from the communication device B within a predetermined period after the C-Req frame was transmitted from the CRC of the transmitter Tx, the same C-Req frame is resent as described above for the maximum number of times to resent N (or until the time limit of the time limit T1 is reached) (however, the diagrammatic representation of the resending sequence is omitted to simplify the diagram in FIG. 16).

Next, this time, the communication device A transmits a C-Req frame from the ECS of the transmitter Tx so as to establish a connection using the first error correction method. With regard to the physical layer header of the C-Req frame, a header check sequence which is generated using the first error detection method is set and the value “y”, which shows that the header check sequence which is generated in accordance with the first error detection method is set, is written in the version region of the physical layer header.

In addition, in the communication device A, when an ACK frame is not able to be received from the communication device B within a predetermined period after the C-Req frame was transmitted from the ECS of the transmitter Tx, the same C-Req frame is resent as described above for the maximum number of times to resent M (or until the time limit of the time limit T2 is reached) (however, the diagrammatic representation of the resending sequence is omitted to simplify the diagram in FIG. 16).

At this time, the communication device B operates only the CRC of the receiver Rx. The second header check sequence of the C-Req frame is set to be generated using the first error detection method. As a result, the communication device B detects an error when receiving the C-Req frame generated in accordance with the first error detection method using the CRC of the receiver Rx and decryption is not possible.

As a result, since the communication device B detects an error when receiving the C-Req frame only using the CRC of the receiver Rx, there is a reply with the C-Acc frame from the CRC of the transmitter Tx. With regard to the physical layer header of the C-Acc frame, the communication device B sets a header check sequence which is generated using the second error detection method and writes the value “x”, which shows that the header check sequence which is generated in accordance with the second error detection method is set, in the version region of the physical layer header.

At this time, the communication device A operates both the CRC and the ECS of the receiver Rx. The header check sequence of the C-Acc frame is set to be generated using the second error detection method. Accordingly, in the communication device A, reception is successful in the CRC of the receiver Rx but an error is detected in the header check sequence and reception fails in the ECS. Then, when the physical layer header of the C-Acc frame which is received by the CRC of the receiver Rx is decrypted and it is confirmed that the value “x” is written in the version region, the communication device A is able to recognize that the communication device B which is the connection request destination has generated the header check sequence using the second error detection method. Therefore, in the communication device A, the ECS of the receiver Rx is not used, that is, the operation of the first transmission and reception processing section 42 is stopped.

In addition, in the communication device B, when an ACK frame is not able to be received from the communication device A within a predetermined period after the C-Acc frame is transmitted from the CRC of the transmitter Tx, the same C-Acc frame is resent as described above for the maximum number of times to resent N (or until the time limit of the time limit T1 is reached) (here, it is shown that N2 in the example shown in FIG. 16).

At this time, the communication device A operates only the CRC in each of the transmitter Tx and the receiver Rx. The header check sequence of the C-Acc frame is set to be generated using the second error detection method. When the communication device A is successful in the reception of the C-Acc frame using the CRC of the receiver Rx, the physical header is decrypted, and it is confirmed that “x” is written in the version region, there is a reply with an ACK frame from the CRC of the transmitter Tx. With regard to the physical layer header of the ACK frame, a header check sequence which is generated using the second error detection method is set and the value “x”, which shows that the header check sequence which is generated in accordance with the second error detection method is set, is written in the version region of the physical layer header.

The communication device B operates only the CRC of the receiver Rx. The header check sequence of the ACK frame is set to be generated using the second error detection method. When the communication device B is successful in the reception of the ACK frame using the CRC of the receiver Rx, the physical header is decrypted, and it is confirmed that “x” is written in the version region, it is possible to confirm that a connection is established in accordance with the second error detection method.

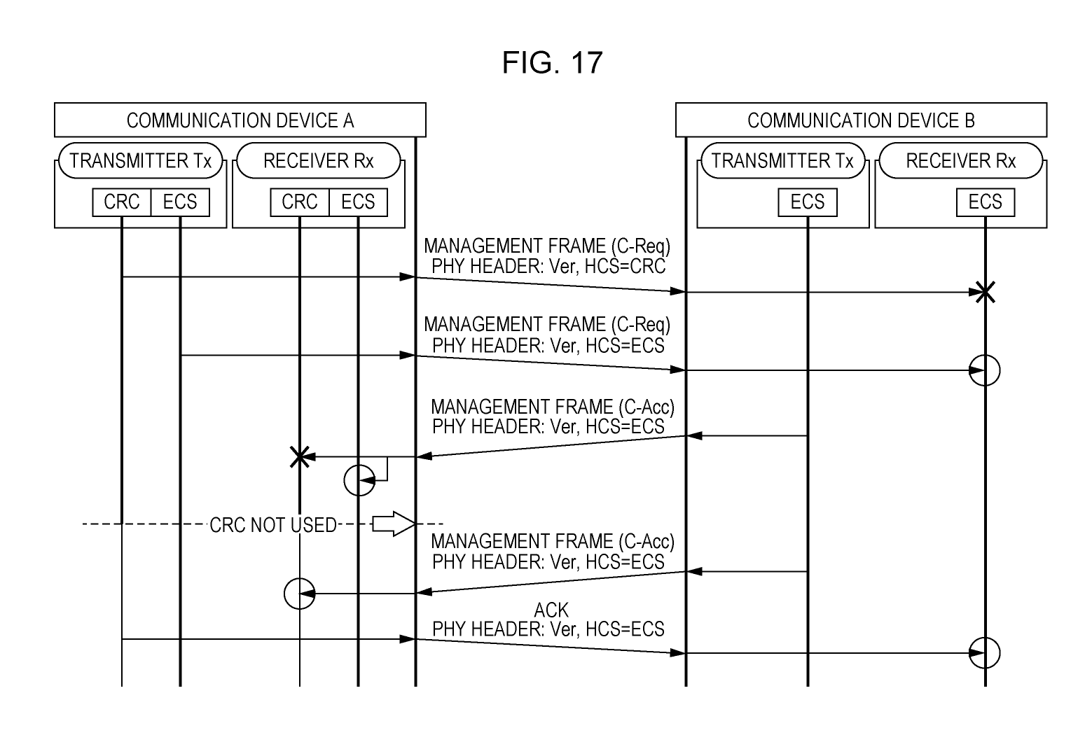

FIG. 17 illustrates another communication sequence example where an error detection method is switched when frame resending has reached a time limit. In the communication sequence example in the diagram, a connection is established between the (new model of) communication device (refer to FIG. 4) which adopts the second error detection method and ensures upward compatibility with the second error detection method and the (existing model of) communication device (refer to FIG. 9) which adopts the second error detection method. In FIG. 17, the communication device which is the connection request origin (or the active side) is the “communication device A” and the communication device which is the connection request destination (or the passive side) is the “communication device B”. In addition, in each of the communication devices A and B, transmitters are represented by “Tx” and receivers are represented by “Rx”, and in each of the transmitters and receivers, functional blocks equivalent to the first transmission and reception processing sections 42 or 92 are represented by “ECS” and a functional block equivalent to the second transmission and reception processing sections 43 is represented by “CRC”. In addition, the periods where each of the functional blocks is operating are represented by solid lines. In addition, in order to simplify the description, the frame resending sequence has been appropriately omitted.

The communication device A which is the connection request origin operates the CRC and the ECS of the transmitter Tx at the same time and operates the CRC and the ECS of the receiver Rx at the same time when waiting for reception. Then, the communication device A transmits the connection request C-Req frame by switching alternately between the CRC and the ECS of the transmitters Tx at a predetermined frequency. On the other hand, the communication device B which is the connection request destination operates the ECS of the transmitter Tx and the receiver Rx when waiting for reception. When waiting for reception, the receivers Rx are made to intermittently receive.

The communication device A initially transmits a C-Req frame from the CRC of the transmitter Tx so as to request a connection using the second error correction method. With regard to the physical layer header of the C-Req frame, a header check sequence which is generated using the second error detection method is set and the value “x”, which shows that the header check sequence which is generated in accordance with the second error detection method is set, is written in the version region of the physical layer header.

The communication device B is provided with only the ECS of the receiver Rx, and operates the ECS of the receiver Rx when waiting for reception. Since the header check sequence of the C-Req frame is set to be generated using the second error detection method, the communication device B detects an error when receiving the C-Req frame using the ECS of the receiver Rx and decryption is not possible. In this case, there is no replying with the C-Acc frame from the communication device B.

In addition, in the communication device A, when an ACK frame is not able to be received from the communication device B within a predetermined period after the C-Req frame was transmitted from the CRC of the transmitter Tx, the same C-Req frame is resent as described above for the maximum number of times to resent N (or until the time limit of the time limit T1 is reached) (however, the diagrammatic representation of the resending sequence is omitted to simplify the diagram in FIG. 17).

Next, this time, the communication device A transmits a C-Req frame from the ECS of the transmitter Tx so as to request a connection using the first error correction method. With regard to the physical layer header of the C-Req frame, a header check sequence which is generated using the first error detection method is set and the value “y”, which shows that the header check sequence which is generated in accordance with the first error detection method is set, is written in the version region of the physical layer header.

In addition, in the communication device A, when an ACK frame is not able to be received from the communication device B within a predetermined period after the C-Req frame was transmitted from the ECS of the transmitter Tx, the same C-Req frame is resent as described above for the maximum number of times to resent M (or until the time limit of the time limit T2 is reached) (however, the diagrammatic representation of the resending sequence is omitted to simplify the diagram in FIG. 17).

When the communication device B is successful in the reception of the second C-Acc frame using the ECS of the receiver Rx, there is a reply with a C-Acc frame from the ECS of the transmitter Tx. With regard to the physical layer header of the C-Acc frame, a header check sequence which is generated using the first error detection method is set and the value “y”, which shows that the header check sequence which is generated in accordance with the first error detection method is set, is written in the version region of the physical layer header.

At this time, the communication device A operates both the CRC and the ECS of the receiver Rx. The header check sequence of the C-Acc frame is set to be generated using the first error detection method. Accordingly, in the communication device A, reception is successful in the ECS of the receiver Rx but an error is detected in the header check sequence and reception fails in the CRC. Then, when the physical layer header of the C-Acc frame which is received by the ECS of the receiver Rx is decrypted and it is confirmed that the value “y” is written in the version region, the communication device A is able to recognize that the communication device B which is the connection request destination has generated the header check sequence using the first error detection method. Therefore, in the communication device A, the CRC of the transmitter Tx and the receiver Rx is not used, that is, the operation of the second transmission and reception processing section 43 is stopped.

In addition, in the communication device B, when an ACK frame is not able to be received from the communication device A within a predetermined period after the C-Acc frame was transmitted from the ECS of the transmitter Tx, the same C-Acc frame is resent as described above.

At this time, the communication device A operates only the ECS of the transmitter Tx and the receiver Rx. The header check sequence of the C-Acc frame is set to be generated using the first error detection method. When the communication device A is successful in the reception of the C-Acc frame using the ECS of the receiver Rx, the physical header is decrypted, and it is confirmed that “y” is written in the version region, there is a reply with an ACK frame from the ECS of the transmitter Tx. With regard to the physical layer header of the ACK frame, a header check sequence which is generated using the first error detection method is set and the value “y”, which shows that the header check sequence which is generated in accordance with the first error detection method is set, is written in the version region of the physical layer header.

When the communication device B receives the ACK frame from the communication device A using the ECS of the receiver Rx, it is possible to confirm that a connection is established.

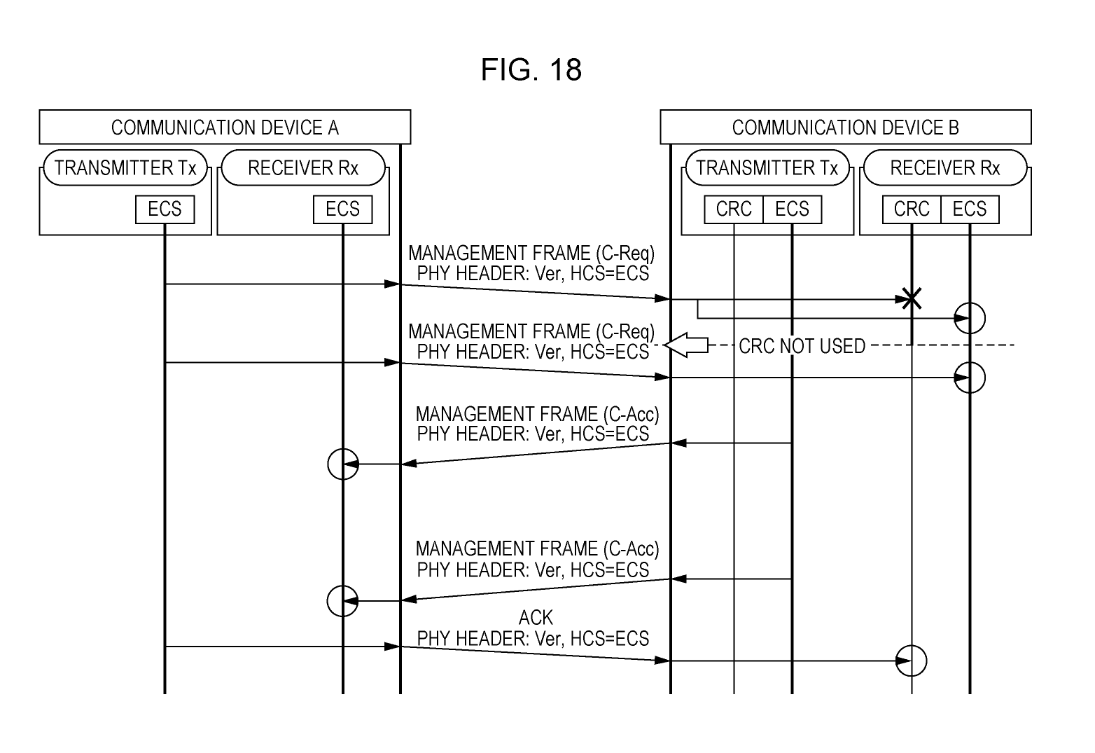

FIG. 18 illustrates another communication sequence example where an error detection method is switched when frame resending has reached a time limit. In the communication sequence example in the diagram, a connection is established between the (existing model of) communication device (refer to FIG. 9) which adopts the first error detection method and the (new model of) communication device (refer to FIG. 4) which adopts the second error detection method and ensures upward compatibility with the first error detection method. In FIG. 18, the communication device which is the connection request origin (or the active side) is the “communication device A” and the communication device which is the connection request destination (or the passive side) is the “communication device B”. In addition, in each of the communication devices A and B, transmitters are represented by “Tx” and receivers are represented by “Rx”, and in each of the transmitters and receivers, functional blocks equivalent to the first transmission and reception processing sections 42 or 92 are represented by “ECS” and a functional block equivalent to the second transmission and reception processing sections 43 is represented by “CRC”. In addition, the periods where each of the functional blocks is operating are represented by solid lines. In addition, in order to simplify the description, the frame resending sequence has been appropriately omitted.

The communication device A which is the connection request origin operates the ECS of the transmitter Tx and the receiver Rx when waiting for reception. On the other hand, the communication device B which is the connection request destination operates the CRC and the ECS of the transmitter Tx at the same time and operates the CRC and the ECS of the receiver Rx at the same time when waiting for reception. When waiting for reception, the receivers Rx are made to intermittently receive.

The communication device A transmits a C-Req frame from the ECS of the transmitter Tx so as to request a connection using the first error correction method. With regard to the physical layer header of the C-Req frame, a header check sequence which is generated using the first error detection method is set and the value “y”, which shows that the header check sequence which is generated in accordance with the first error detection method is set, is written in the version region of the physical layer header.

At this time, the communication device B operates both the CRC and the ECS of the receiver Rx. The header check sequence of the C-Req frame is set to be generated using the first error detection method. Accordingly, in the communication device B, reception is successful in the ECS of the receiver Rx but an error is detected in the header check sequence and reception fails in the CRC. Then, when the physical layer header of the C-Req frame which is received by the ECS of the receiver Rx is decrypted and it is confirmed that the value “y” is written in the version region, since the communication device B is able to recognize that the communication device A which is the connection request origin has generated the header check sequence using the first error detection method, the CRC of the receiver Rx is not used, that is, the operation of the second transmission and reception processing section 43 is stopped.

On the other hand, in the communication device A, when a C-Acc frame is not able to be received from the communication device B within a predetermined period after the C-Req frame was transmitted from the ECS of the transmitter Tx, the same C-Req frame is resent as described above (however, the diagrammatic representation of the resending sequence is omitted to simplify the diagram in FIG. 18).

At this time, the communication device B operates only the ECS of the receiver Rx and it is possible to detect an error when receiving the C-Req frame. Then, the communication device B replies with a C-Acc frame from the ECS of the transmitter Tx. With regard to the physical layer header of the C-Acc frame, the communication device B sets a header check sequence which is generated using the first error detection method and writes the value “y”, which shows that the header check sequence which is generated in accordance with the first error detection method is set, in the version region of the physical layer header.

In addition, in the communication device B, when an ACK frame is not able to be received from the communication device A within a predetermined period after the C-Acc frame is transmitted from the ECS of the transmitter Tx, the same C-Acc frame is resent as described above for the maximum number of times to resent M (or until the time limit of the time limit T2 is reached) (here, it is shown that M≧2 in the example shown in FIG. 18).

The communication device A is able to detect an error when receiving the resent C-Acc frame using the ECS of the receiver Rx. Then, the communication device A replies with an ACK frame from the ECS of the transmitter Tx.

When the communication device B receives the ACK frame from the communication device A, it is possible to confirm that a connection is established.

In this manner, according to the communication sequence examples shown in FIGS. 16 to 18, a parity conversion process as shown in FIGS. 1B and 2 is not performed in the second error detection method, but the communication device which applies the second error detection method is able to establish a connection with the communication device which applies the first error detection method.

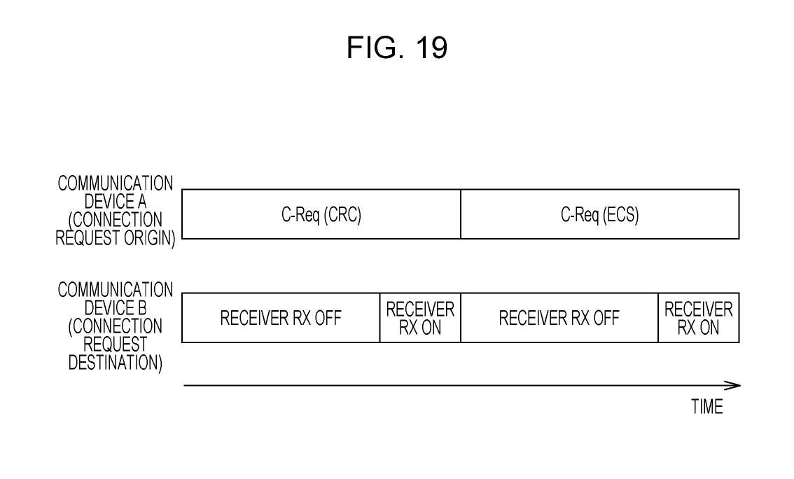

Here, the communication sequence examples shown in FIGS. 16 to 18, the communication device A which is the connection request origin transmits a C-Req frame by switching alternately between the CRC and the ECS of the transmitters Tx at a predetermined frequency. On the other hand, the communication device B which is the connection request destination waits for reception of the C-Req frame while making the receiver Rx receive intermittently (refer to FIG. 19). If the communication device B is a responder which operates passively, it is desirable to receive intermittently from the point of view of low power consumption. The duty cycle of the intermittent receiving varies for each device. In a case such as this, it is necessary that the communication device A sets the switching frequency of transmitting the C-Req frame from the CRC and the ECS considering the longest off period when the receiver Rx is sleeping at the side of the communication device B. As a result, there is a possibility that there are situations when time is necessary for the communication device B to be able to connect by receiving the C-Req frame from the communication device A or connection is not possible.

It should be understood by those skilled in the art that various modifications, combinations, sub-combinations and alterations may occur depending on design requirements and other factors insofar as they are within the scope of the appended claims or the equivalents thereof.

What is claimed is:

1. A code generating device comprising:
a code word generating section which generates a code word with a predetermined code word length by applying a second matrix Gq of a second error detection method with regard to an information word A′ which has been input; and
a code word conversion section which converts the code word generated by the code word generating section based on an added fixed value (Qa+Pa) which is formed from respective code words Qa and Pa which are obtained by the second matrix Gq and a first matrix Gp of a first error detection method being respectively applied to an information word A which is formed from a specific data string.

2. The code generating device according to claim 1,
wherein the code word conversion section converts the code word, which is generated by the code word generating section from the information word A′ which is input, based on the added fixed value (Qa+Pa) in accordance with a conversion method which converts the code word Qa, which is obtained by applying the second matrix Gq to the information word A which is formed from the specific data string, to the code word Pa, which is obtained by applying the first matrix Gp to the information word A.

3. The code generating device according to claim 1,
wherein the code word conversion section converts by the added fixed value (Qa+Pa) being attached to the code word which is generated by the code word generating section from the information word A′ which has been input.

4. A code generating device comprising:
a fixed value holding section which holds a fixed value K from which an added fixed value (Qa+Pa), which is formed from respective code words Qa and Pa which are obtained by a second matrix Gq and a first matrix Gp of a first error detection method being respectively applied to an information word A which is formed from a specific data string, is able to be obtained when the second matrix Gq is applied after a bit position is shifted from a least significant bit to a higher order by n bits;
a fixed value adding section which adds the fixed value K to an input information word A′ at a position which is shifted from a least significant bit to a higher order by n bits; and
a code word generating section which generates a code word with a predetermined code word length by applying the second matrix Gq to the information word A′ after the fixed value K is added.

5. A code generating method comprising:
generating a code word with a predetermined code word length by applying a second matrix Gq of a second error detection method with regard to an information word A′ which has been input; and
converting the generated code word based on an added fixed value (Qa+Pa) which is formed from respective code words Qa and Pa which are obtained by the second matrix Gq and a first matrix Gp of a first error detection method being respectively applied to an information word A which is formed from a specific data string.

6. A code checking device comprising:
a code word generating section which inputs a code word generated using the code generating device of claim 1 with an original information word A′ and generates a code word with a predetermined code word length by applying a second matrix Gq of a second error detection method with regard to the original information word A′;
a code word inverse conversion section which inversely converts the code word input with the original information word A′ based on an added fixed value (Qa+Pa) which is formed from respective code words Qa and Pa which are obtained by the second matrix Gq and a first matrix Gp of a first error detection method being respectively applied to an information word A which is formed from a specific data string; and
a checking section which checks by comparing the code word generated by the code word generating section from the original information word A′ and the code word after inverse conversion by the code word inverse conversion section.

7. The code checking device according to claim 6,
wherein the code word inverse conversion section inversely converts the code word which is input with the original information word A′ based on the added fixed value (Qa+Pa) in accordance with a conversion method which converts the code word Qa, which is obtained by applying the second matrix Gq to the information word A which is formed from the specific data string, to the code word Pa, which is obtained by applying the first matrix Gp to the information word A.

8. The code checking device according to claim 6,
wherein the code word inverse conversion section inversely converts by the added fixed value (Qa+Pa) being attached to the code word which is input with the original information word A′.

9. A code checking device comprising:
a fixed value holding section which inputs a code word generated using the code generating device of claim 1 with an original information word A′ and which holds a fixed value K from which an added fixed value (Qa+Pa), which is formed from respective code words Qa and Pa which are obtained by a second matrix Gq and a first matrix Gp of a first error detection method being respectively applied to an information word A which is formed from a specific data string, is able to be obtained when the second matrix Gq is applied after a bit position is shifted from a least significant bit to a higher order by n bits;
a fixed value adding section which adds the fixed value K to the original information word A′ at a position which is shifted from a least significant bit to a higher order by n bits;
a code word generating section which generates a code word with a predetermined code word length by applying the second matrix Gq to the information word A′ after the fixed value K is added; and
a checking section which checks by comparing the code word generated by the code word generating section with the code word which was input with the original information word A′.

10. A code checking method comprising:
inputting a code word generated using the code generating method of claim 5 with an original information word A′;
generating a code word with a predetermined code word length by applying a second matrix Gq of a second error detection method with regard to the original information word A′;
inversely converting the code word input with the original information word A′ based on an added fixed value (Qa+Pa) which is formed from respective code words Qa and Pa which are obtained by the second matrix Gq and a first matrix Gp of a first error detection method being respectively applied to an information word A which is formed from a specific data string; and
checking by comparing the code word generated from the original information word A′ and the code word after the inverse converting.

11. A computer program which is written in a computer readable format so as to make a computer to function as the sections comprising:
a code word generating section which generates a code word with a predetermined code word length by applying a second matrix Gq of a second error detection method with regard to an information word A′ which has been input; and
a code word conversion section which converts the code word generated by the code word generating section based on an added fixed value (Qa+Pa) which is formed from respective code words Qa and Pa which are obtained by the second matrix Gq and a first matrix Gp of a first error detection method being respectively applied to an information word A which is formed from a specific data string.

12. A computer program which is written in a computer readable format so as to make a computer to function as the sections comprising:
a code word generating section which inputs a code word generated using the code generating device of claim 1 with an original information word A′ and generates a code word with a predetermined code word length by applying a second matrix Gq of a second error detection method with regard to the original information word A′;
a code word inverse conversion section which inversely converts the code word input with the original information word A′ based on an added fixed value (Qa+Pa) which is formed from respective code words Qa and Pa which are obtained by the second matrix Gq and a first matrix Gp of a first error detection method being respectively applied to an information word A which is formed from a specific data string; and
a checking section which checks by comparing the code word generated by the code word generating section from the original information word A′ and the code word after inverse conversion by the code word inverse conversion section.

13. A communication device comprising:
a first transmission and reception processing section which generates a parity from transmission data and performs checking of a parity in accordance with a first error detection method;
a second transmission and reception processing section which generates a parity from transmission data and performs checking of a parity in accordance with a second error detection method where the same parity as the first error detection method is generated only in regard to specific transmission data; and
a communication control section which controls the first and second transmission and reception processing sections in accordance with a communication sequence.

14. The communication device according to claim 13,
wherein the first transmission and reception processing section of the communication device is provided with a first parity generation section which generates a parity with a predetermined code word length by applying a first matrix Gp with regard to transmission data, and a first parity checking section which generates a parity by applying a first matrix Gp with regard to received data and performs error detection by comparing the generated parity with the parity which is connected to the received data, and
the second transmission and reception processing section is provided with a second parity generating section which, after generating a parity with a predetermined code word length by applying a second matrix Gq with regard to transmission data, converts the generated parity using an added fixed value (Qa+Pa) which is formed from respective code words Qa and Pa which are obtained by the second matrix Gq and the first matrix Gp being respectively applied to specific transmission data, and a second parity checking section which generates a parity by applying the second matrix Gq with regard to received data, inversely converts the parity which is connected to the received data using the added fixed value (Qa+Pa), and performs error detection by comparing the generated parity with the inversely converted parity.

15. The communication device according to claim 13,
wherein the second parity generating section converts by the added fixed value (Qa+Pa) being attached to the parity which is generated by applying the second matrix Gq with regard to the transmission data, and
the second parity checking section inversely converts by the added fixed value (Qa+Pa) being attached to the parity which is connected to received data.

16. The communication device according to claim 13,
wherein the specific transmission data includes method information which shows which out of the first error detection method and the second error detection method is used in the following communication process, and
the communication control section controls a communication operation of the first transmission and reception processing section and the second transmission and reception processing section based on the method information which is included in the specific transmission data which is received by the second transmission and reception processing section.

17. The communication device according to claim 13,
wherein a communication sequence is applied where a connection is established via a connection request origin transmitting a connection request frame, a connection request destination replying with a connection request acceptance frame, and the connection request origin transmitting a confirmation response frame, and
the specific transmission data is equivalent to a physical layer header of the connection request frame and includes method information which shows in the physical layer header which out of the first error detection method and the second error detection method is used in the following communication process.

18. The communication device according to claim 17,
wherein the communication control section makes both the first and the second transmission and reception processing sections wait for reception of the connection request acceptance frame after transmitting the connection request frame, which includes the methods information showing the use of the second error detection method in the physical layer header, from the second transmission and reception processing section, establishes a connection using the first error detection method, when the connection request acceptance frame is able to be received by the first transmission and reception processing section, by confirming that the method information which shows the use of the first error detection method is included in the physical layer header of the frame and transmitting the confirmation response frame from the first transmission and reception processing section, and establishes a connection using the second error detection method, when the connection request acceptance frame is able to be received by the second transmission and reception processing section, by confirming that the method information which shows the use of the second error detection method is included in the physical layer header of the frame and transmitting the confirmation response frame from the second transmission and reception processing section.

19. The communication device according to claim 17,
wherein the communication control section makes both the first and the second transmission and reception processing section wait for reception of the connection request frame, establishes a connection using the first error detection method, when the connection request frame is able to be received by the second transmission and reception processing section, by confirming that the method information which shows the use of the second error detection method is included in the physical layer header of the frame, transmitting the connection request acceptance frame from the first transmission and reception processing section, and performing a confirmation response using the first transmission and reception processing section, and establish a connection using the first error detection method, when the connection request frame is able to be received by the first transmission and reception processing section, by confirming that the method information which shows the use of the first error detection method is included in the physical layer header of the frame, transmitting the connection request acceptance frame from the first transmission and reception processing section, and performing a confirmation response using the first transmission and reception processing section.
